(19) United States
(12) Patent Application Publication
(10) Pub. No.: US 2006/0233009 A1
(43) Pub. Date: Oct. 19, 2006

(54) Interleaving and de-interleaving methods, wireless apparatus and semiconductor apparatus of same

(75) Inventor: Koji Hika, Tokyo (JP)

Correspondence Address: WOODCOCK WASHBURN LLP, ONE LIBERTY PLACE, 46TH FLOOR, 1650 MARKET STREET, PHILADELPHIA, PA, 19103, US

(73) Assignee: Kabushiki Kaisha Toyota Jidoshokki, Kariya-shi (JP)

(21) Appl. No.: 11/393,547

(22) Filed: Mar. 30, 2006

(30) Foreign Application Priority Data
Mar. 31, 2005 (JP) 2005-101070

(51) Int. Cl. G11C 19/08

(52) U.S. Cl. 365/1

(57) ABSTRACT

The purpose of the present invention is to simplify a circuit for carrying out an interleaving and a de-interleaving processing. A RAM address control outputs an address by an addition of an address output from an address ROM and a predetermined offset, based on state information. The address ROM stores address data corresponding to a rearrangement rule for data of each modulation system. A de-interleaving or an interleaving processing is accomplished by reading out of a RAM, or writing thereto, the data of an address specified by the RAM address control.

### CROSS REFERENCE TO RELATED APPLICATION

This application claims priority to Japanese application number 2005-101070 filed Mar. 31, 2005.

### BACKGROUND OF THE INVENTION

1. Field of the Invention

The present invention relates to an interleaving and a de-interleaving method, and to a wireless apparatus and it's semiconductor apparatus which have an interleaving and a de-interleaving function.

2. Description of the Related Art

Data transmission of a terrestrial digital broadcast, wireless LAN (local area network), et cetera, use an OFDM (Orthogonal Frequency Division Multiplexing).

A patent document 1 notes a technique for performing an inverse Fourier transform processing for a transmission and a Fourier transform processing for receiving, both by using Fourier transform means, setting the conversion result thereof in an output register and reading the data set therein in different sequences between the time of transmission and reception in an apparatus for transmitting and receiving data by the OFDM. This eliminates a necessity of a specific circuit for output processing in the Fourier transform means.

A patent document 2 notes a technique for making a frequency de-interleaving table, which stores a readout address, corresponding to a modulation method and the number of segments for each modulation method for the purpose of performing de-interleaving by referring to the frequency de-interleaving table.

The invention of the patent document 2, has the intent of saving the size of memory used at the time of a frequency interleaving, there is, however, a necessity to make frequency interleaving tables corresponding to the number of segments of each modulation method and accordingly there is a limitation in the size of saved memory. Furthermore, the invention of the patent document 2 is not intended to make a size of a circuit for accomplishing the interleaving and de-interleaving compact.

Let a conventional method for rearranging data for an interleaving and de-interleaving be described by referring to FIGS. 1 and 2.

FIG. 1 is a diagram illustrating a configuration of a RAM 17 (i.e., a memory map), showing that, as viewed from the front of FIG. 1, the characters A0, B0, C0 through F2, which are lined up horizontally at the top of the RAM 17 indicate the columns, while the numbers 0, 1, 2, 3 through 15, which are lined up vertically on the left, indicate the lines. Writing the input data a, b, c, et cetera, sequentially in the column direction of the RAM 17 and rearranging the data at the time of reading out in the line direction makes it possible to rearrange the data in a prescribed sequence. For example, writing bit by bit in the column direction from the column A0 of the RAM 17 and reading out bit by bit in the line direction from the line 0 (zero), i.e., a q G W and so on, as shown by FIG. 1, enables a rearrangement of a continuous bit string to a position which is separated by 16 bits.

A rearrangement rule of data of each modulation method of the interleaving is defined as shown by FIG. 2.

FIG. 2 shows rearrangement rules both for data without permutation and with permutation which are related to the modulation methods.

Referring to FIG. 2, the ROW_0_2 and ROW_1_2 of the 16 QAM modulation, and the ROW_0_3, ROW_1_3, ROW_2_3 of the 64 QAM modulation are lines designated by a value of the remainder when dividing the line number shown in FIG. 1 by “2” or “3”, respectively.

For example, the ROW_1_2 indicates an odd numbered line because the remainder is “1” when dividing the line number by two (2), while the ROW_0_2 indicates an even numbered line because the remainder is “0” when dividing the line number by two (2). And An, Bn and so on are displayed for n=0, 1, 2, accordingly indicating A0, B0 and so on; A1, B1 and so on; and A2, B2 and so on as shown by FIG. 1.

As shown by FIG. 2, in the case of rearranging data in the 16 QAM modulation method, the even numbered line of the ROW_0_2 has the same data arrangement as in the case of not rearranging the data. And, in the odd numbered line of the ROW_1_2, the An of the zeroth bit and the Bn of the first bit are interchanged; the En of the third bit and the Dn of the fourth bit are interchanged; and zero (0) is set for the other bits. Note that the zeroth bit, first bit through fifth bit are defined from the An side of the “without permutation” shown by FIG. 2.

In the case of rearranging the data by the 64 QAM modulation method, the ROW_0_3, that is, the column with the remainder being zero (0) when dividing the line number by three (3), has the same sequence as in the case of not rearranging the data.

As for the ROW_1_3, that is, the line with the remainder being one (1) when dividing the line number by three (3), the rearrangement of data is performed so that the zeroth bit becomes Bn, the first bit becomes Cn, the second bit becomes An, the third bit becomes En, the fourth bit becomes Fn and the fifth bit becomes Dn.

As for the ROW_2_3, that is, the line with the remainder being two (2) when dividing the line number by three (3), the rearrangement of data is performed so that the zeroth bit becomes Cn, the first bit becomes An, the second bit becomes Bn, the third bit becomes Fn, the fourth bit becomes Dn, and the fifth bit becomes En. This is to carry out the processing of converting the arrangement of the “without permutation” to that of the “with permutation” in an interleaving processing. De-interleaving carries out the processing of reverting the rearranged data back to the original arrangement. That is to carry out the processing of converting the arrangement of the “with permutation” to that of the “without permutation”.

The conventional method for rearranging data in the interleaving and de-interleaving method requires a processing unit for the interleaving separate from that for the de-interleaving, hence causing the problem of the circuit sizes becoming large. Furthermore, if an interleaving processing operates mutually independently from a de-interleaving processing, separate memories are required for an interleaving and a de-interleaving, hence causing the problem of the circuit sizes becoming large.

[Patent document 1] a laid-open Japanese patent application publication No. 11-308190

[Patent document 2] a laid-open Japanese patent application publication No. 2003-124904

### SUMMARY OF THE INVENTION

The intent of the present invention is to simplify a circuit required for an interleaving processing and a de-interleaving processing.

According to the present invention, an interleaving and de-interleaving method for rearranging data makes a state control unit output state information for the purpose of selecting a RAM (random access memory) as the access target from among a plurality of RAM and specifying an address, wherein the state control unit outputs state information of a first mode for rearranging data and that of a second mode for not rearranging data.

This invention enables a circuit for an interleaving processing common with that for a de-interleaving processing, thereby making the circuit size small. And a small circuit size reduces the power consumption.

The interleaving and de-interleaving method according to the above described invention makes a state control unit output state information for the purpose of selecting the RAM as the access target from among a plurality of RAM and specifying the address, address data for specifying addresses, which are stored by a ROM (read only memory), of the plurality of RAM outputted by specifying readout addresses of the ROM based on the state information, and a selection signal for selecting a RAM as the access target outputted based on the state information, wherein the state control unit outputs state information of a first mode for rearranging data and that of a second mode for not rearranging data.

Such a configuration enables a circuit for an interleaving processing common with that for a de-interleaving processing, thereby making the circuit size small. And a small circuit size reduces the power consumption.

The interleaving and de-interleaving method according to the above described invention outputs an address, which is an addition of a unit offset determined by the state information and address data outputted from the ROM, to the RAM as the access target.

Such a configuration enables a rearrangement of data by reading out data in a prescribed address interval by changing a unit offset.

The interleaving and de-interleaving method according to the above described invention rearranges data by specifying the address of the RAM as the access target among the plurality of RAM based on the state information of the first mode and reading out, or writing data, and at the same time specifies the address of a RAM as the access target among the plurality of RAM based on the state information of the second mode.

The above described configuration makes it possible to rearrange the data by specifying the address of the RAM as the access target among the plurality of RAM according to the state information of the first mode and at the same time carrying out the other of data writing or reading for another RAM as the access target among the plurality of RAM. This enables a high speed interleaving and de-interleaving processing.

The interleaving and de-interleaving method according to the above described invention outputs a selection signal for selecting the RAM as the access target based on the state information of the first mode and at the same time outputs a signal for specifying whether to make the RAM the access target of a writing state or a readout state based on the state information of the second mode.

Such a configuration makes it possible to rearrange data by selecting the RAM as the access target based on the state information of the first mode and at the same time carry out the other work of data reading or writing for another RAM. This enables a high speed interleaving and de-interleaving processing.

The interleaving and de-interleaving method according to the above described invention outputs an address, as a readout address, which is obtained by an addition of an address determined corresponding to each of state information of each modulation method and a base address changing synchronously with a first timing signal.

Such a configuration makes it possible to specify an address of a ROM by using the same state information for each modulation system by setting a different address per the modulation system for the same state information for example. This reduces control information for the purpose of specifying an address of a ROM, thereby simplifying an address control of the ROM.

Meanwhile, a wireless apparatus according to the present invention has an interleaving and de-interleaving function for rearranging data in a prescribed sequence and comprises a RAM for writing, and reading out data, a state control unit which specifies an address of the RAM and carries out an interleaving and an de-interleaving process.

And a semiconductor apparatus according to the present invention comprising an interleaving & de-interleaving process unit for rearranging data in a prescribed sequence which comprises a RAM for writing, and reading out data, a state control unit which outputs a first mode state information and a second mode state information for carrying out an interleaving processing and a de-interleaving processing.

Such a configuration enables a circuit for an interleaving processing common with that for a de-interleaving processing.

### BRIEF DESCRIPTION OF THE DRAWINGS

FIG. 1 describes an interleaving;

FIG. 2 shows a rearrangement rule of each modulation system;

FIG. 3 shows a comprisal of an interleaving and de-interleaving processing unit 11 of an embodiment;

FIG. 4 is a detailed block diagram of the interleaving and de-interleaving processing unit 11;

FIG. 5 illustrates interleaving and de-interleaving processes;

FIG. 6 describes writing and reading input data;

FIG. 7A through 7D shows structures of RAM data;

FIG. 8 shows data structures of RAM_A and RAM_B;

FIG. 9 shows data structures of RAM_A@0, RAM_A@1, RAM_B@0 and RAM_B@1;

FIG. 10A and 10B shows an operating condition of a state control and state information of each modulation system;

FIG. 11A and 11B shows a transition of state information of mode-1 and mode-2;

FIG. 12 shows an operating condition and data structure of an address ROM;

FIG. 13 shows an operating condition of a ROM address control and an address offset table;

FIG. 14A and 14B shows an operating condition of a RAM address control, a unit offset table and a control method for an access position of a RAM;

FIG. 15A and 15B shows an operating condition of a RAM access control and access operation of RAM_A and RAM_B;

FIG. 16 shows a RAM selection table;

FIG. 17 describes a readout operation of an interleaving;

FIG. 18 describes a writing operation of a de-interleaving;

FIG. 19A and 19B shows an operating condition and operation of a zero insertion circuit;

FIG. 20 shows input data and output data of the zero insertion circuit;

FIG. 21 describes a readout operation of a de-interleaving;

FIG. 22 shows an address table;

FIG. 23 shows restored data;

FIG. 24A and 24B exemplifies a conversion of data;

FIG. 25A and 25B exemplifies a conversion of data; and

FIG. 26 shows a data structure in the case of weight data existing.

### DESCRIPTION OF THE PREFERRED EMBODIMENTS

The following is a detailed description of the preferred embodiment of the present invention while referring to the accompanying drawings.

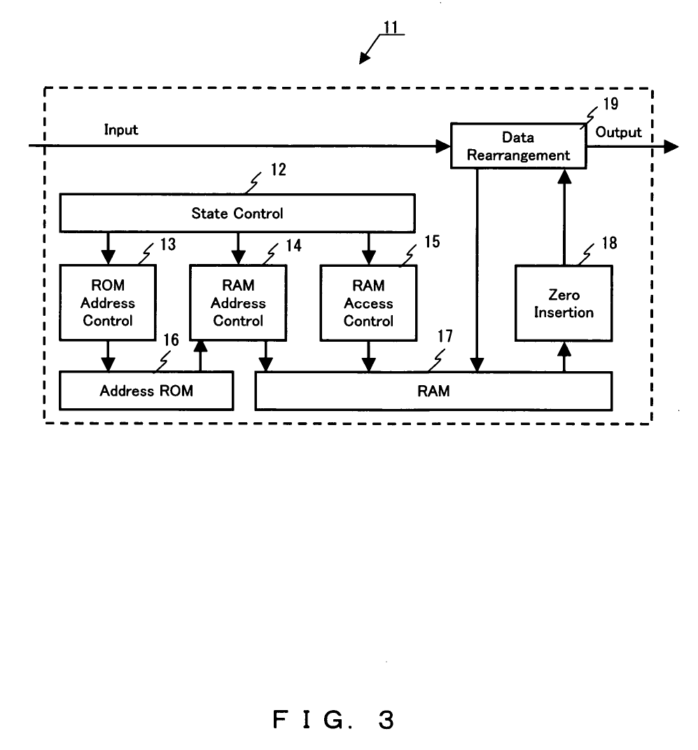

FIG. 3 is a block diagram of an interleaving and de-interleaving processing unit 11 of a wireless apparatus (e.g., a wireless apparatus for carrying out a wireless telecommunication over a wireless LAN, based on a telecommunication protocol per 802.11) according to an embodiment.

Referring to FIG. 3, a state control (corresponding to a state control unit) 12 outputs, to a ROM address control 13, RAM address control 14 and RAM access control 15, state information for the purpose of writing to the RAM 17 by rearranging input data or reading out data stored by the RAM 17 by rearranging the data.

The ROM address control (corresponding to a ROM address control unit) 13 outputs a readout address to an address ROM 16 based on the state information output from the state control 12.

The address ROM 16 stores address data correlated with each modulation system, for the purpose of writing input data in, or reading it out of the RAM 17 by rearranging the input data in a predetermined sequence.

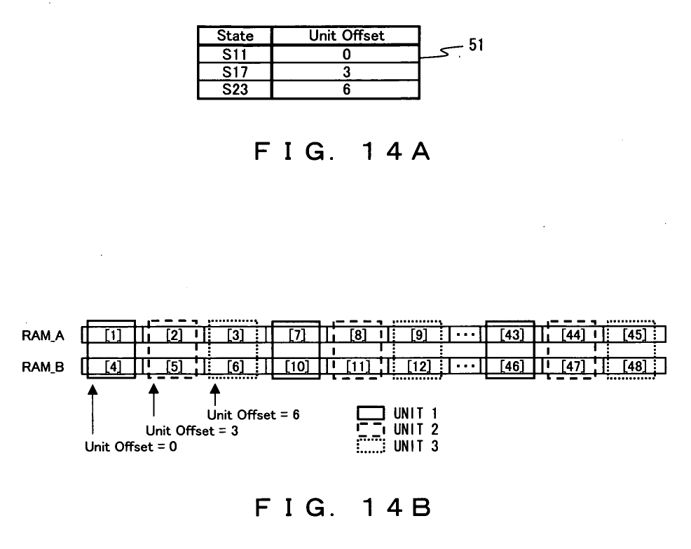

The RAM address control (corresponding to a RAM address control unit) 14 outputs an address, which is an addition of address data outputted from the address ROM 16 and a predetermined unit offset, to the RAM 17 based on the state information output from the state control 12. The unit offset will be described later by referring to FIG. 14.

The RAM access control (corresponding to a RAM access control unit) 15 outputs a signal for selecting a RAM as the access target among a plurality of RAM 17 based on the state information output from the state control 12.

A zero insertion circuit 18 inserts zero (0) at a predetermined position of data read out of the RAM 17, or outputs data read out of the RAM 17 as is.

A data rearrangement unit 19 converts, to a data format matching a circuit on the output side, and outputs input data, or data output from the zero insertion circuit 18.

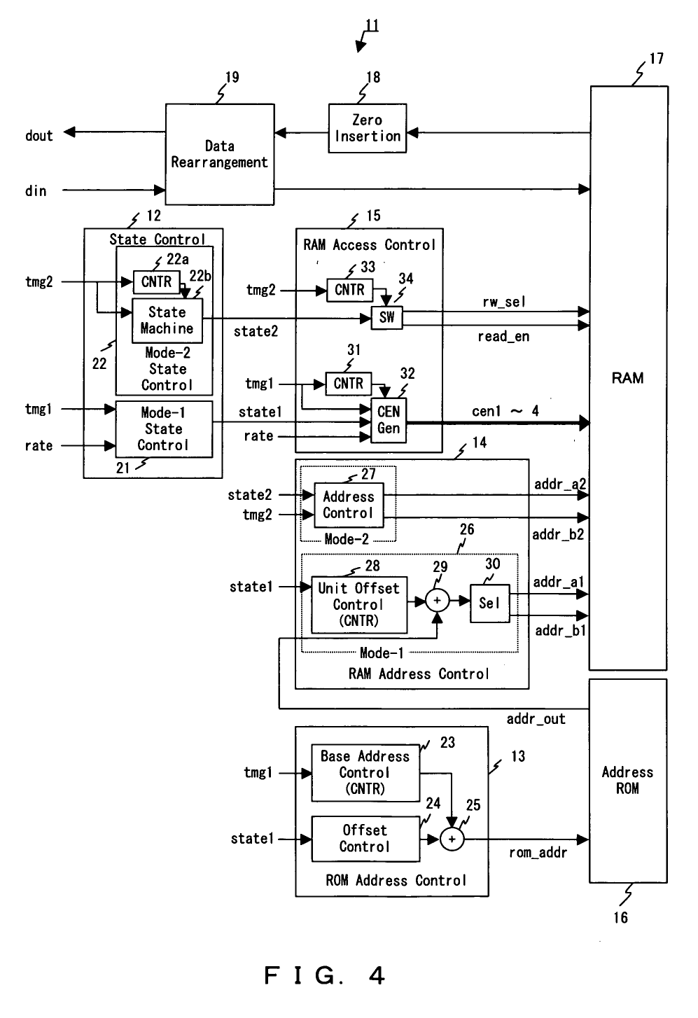

FIG. 4 is a detailed block diagram of the interleaving and de-interleaving processing unit 11.

Referring to FIG. 4, a state control 12 comprises a mode-1 state control 21 and a mode-2 state control 22.

The mode-1 state control 21 outputs a mode-1 state information state1 (i.e., state information of a first mode) based on a mode-1 timing signal tmg1 (i.e., a first timing), which is synchronized with the data, and data rate (NB: this “rate” is a component sign, and not a “datarate”) indicating a modulation system.

The mode-2 state control 22, comprising a counter (CNTR) 22a and a state machine 22b, outputs mode-2 state information state2 (i.e., state information of a second mode) based on a mode-2 timing signal tmg2 (i.e., a second timing signal) which is synchronized with the data.

The ROM address control 13 comprises abase address control 23, an offset control 24 and an adder 25.

The base address control 23, comprising a counter (CNTR) for example, outputs a base address of 0 (zero) through 7 which changes according to, or synchronously with, the timing signal tmg1.

The Offset Control 24 outputs a predetermined address offset determined by mode-1 state information state1.

The adder 25 adds a base address and an offset address, and outputs the address rom_addr of the addition result to the Address ROM 16.

The RAM Address Control 14 comprises a mode-1 address control 26 and a mode-2 address control 27. The mode-1 address control 26 outputs a mode-1 RAM address for rearranging data, while the mode-2 address control 27 outputs a mode-2 RAM address for not rearranging the data.

The mode-1 address control 26 comprises a unit offset control 28 for outputting a unit offset for each unit (which is described later) based on state information state1, an adder 29 for adding address data addr_out, which are read out of the address ROM 16 to the above noted unit offset, and an output unit (sel) 30 for outputting an address addr_a1 for RAM_A and an address addr_b1 for a RAM_B for the mode-1.

The mode-2 address control 27 outputs an address addr_a2 for RAM_A and an address addr_b2 for a RAM_B for the mode-2 based on mode-2 state information state2 and a timing signal tmg2.

The RAM 17 comprises a RAM_A and a RAM_B, with the RAM_A comprising a RAM_A@0 and a RAM_A@1, and the RAM_B comprising a RAM_B@0 and a RAM_B@1. Considering these four RAM, i.e., RAM_A@0, RAM_A@1, RAM_B@0 and RAM_B@1, as one set, then the RAM 17 has a total of 2 sets of RAM (these two sets are called a set #0 and a set #1). Here, the two sets of RAM are classified by separating the @ to 0 or 1 for naming the set #0 for the set with @=0 (i.e., RAM_A00, RAM_A01, RAM_B00 and RAM_B01) and the set #1 for the set with @=1 (i.e., RAM_A10, RAM_A11, RAM_B10 and RAM_B11). That is, the RAM 17 has a total of eight RAM (i.e., RAM_A00, RAM_A01, RAM_B00, RAM_B01, RAM_A10, RAM_A11, RAM_B10 and RAM_B11).

The RAM access control 15 comprises a counter (CNTR) 31 for outputting a signal at a predetermined timing by counting the timing signal tmg1, a selection signal generation unit (CEN generator) 32 for outputting selection signals cen 1 through 4 to the RAM 17 based on model-1 state information state1, a data rate indicating a modulation system, timing signal tmg1 and an output signal of the counter 31, a counter (CNTR) 33 for outputting a signal at a predetermined timing by counting the timing signal tmg2 and a switch circuit 34 for outputting, to the RAM 17, a read enable signal read_en and a signal rw_sel which makes one of two sets of RAM ready for writing, based on state signal state2 and the output signal of the counter 33.

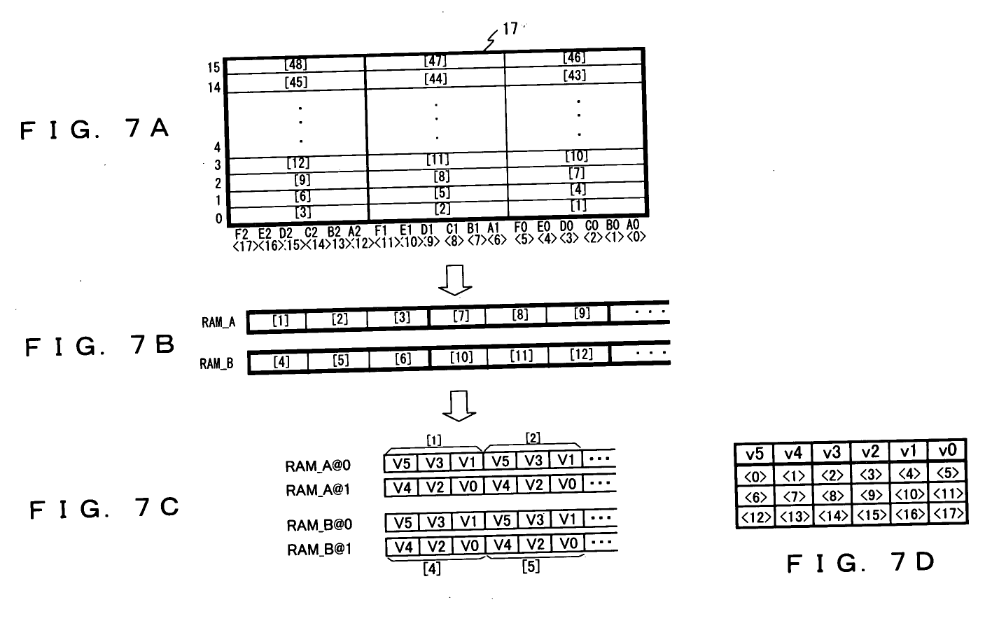

Next, let data structures of the RAM 17 in an interleaving and de-interleaving processing according to the present embodiment be described, by referring to FIGS. 7 through 9.

FIG. 7 is a diagram (memory map) illustrating a data structure of the RAM 17. The RAM 17 shown by FIG. 7A comprises two RAM, i.e., RAM_A and RAM_B, as shown by FIG. 7B, in which 6-bit data [1] through [48] is alternately written in the line direction of the RAM_A and RAM_B, line by line shown by FIG. 7A. Note that the 0, 1, 2 through 15 on the left of the RAM 17 shown by FIG. 7A show the line numbers and therefore the data for one line is the data [1] [2] [3] for example. The <0> through <17> on the bottom of FIG. 7A indicate the column numbers.

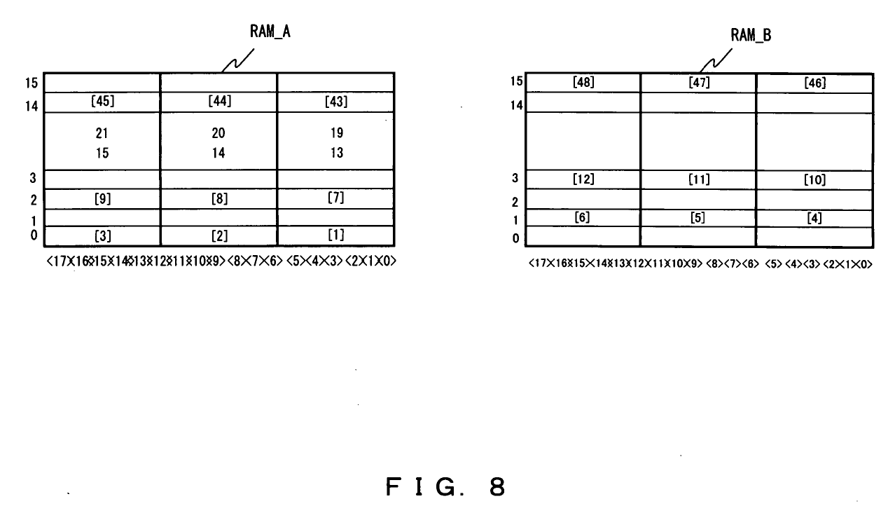

Here, let data stored by the RAM_A and RAM_B be described, by referring to FIG. 8. Regarding the position of the right bottom corner (as viewed from the front of FIG. 8) of the RAM_A as the reference, the columns 0 through 5 of the line 0 (i.e., <0> through <5>) store 6-bit data [1], then the columns 6 through 11 of the same line (i.e., <6> though <11>) store the next 6-bit data [2], and the columns 12 through 17 ((i.e., <12> through <17>) store the next 6-bit data [3].

Likewise in the RAM_B, the columns 0 through 5 on line 1 store 6-bit data [4], the columns 6 through 11 store the data [5] and the columns 12 through 17 store the data [6].

Note that FIG. 8 shows a state of the even number lines of the RAM_A and the odd number lines of the RAM_B storing data so as to correspond to the memory map of the RAM 17 shown by FIG. 7A, the actual fact, however, is that the respective memory areas RAM_A and RAM_B store the data continuously.

Furthermore, the RAM_A and RAM_B respectively comprise RAM_A@0 and RAM_A@1, and RAM_B@0 and RAM_B@1 as shown by FIG. 7C in order to process and store data in parallel.

Now, expressing each bit of data in units of 6-bits [1], [2] and so on, as V5 through V0, as shown by FIG. 7D, the RAM_A@0 stores the zeroth bit data V5, the second bit data V3, and the fourth bit data V1, all of which are from the data [1] as shown by FIG. 7C. And the RAM_A@1 stores the first bit data V4, the third bit data V2, and the fifth bit data V0, all of which are from the data [1]. Likewise in the following, the RAM_A@0 stores 3-bit data V5, V3 and V1 out of the 6-bit data [2], [3], [7], [8] and so on, while the RAM_A@1 stores the remaining 3-bit data V4, V2 and V0. The same applies to the RAM_B@0 and RAM_B@1.

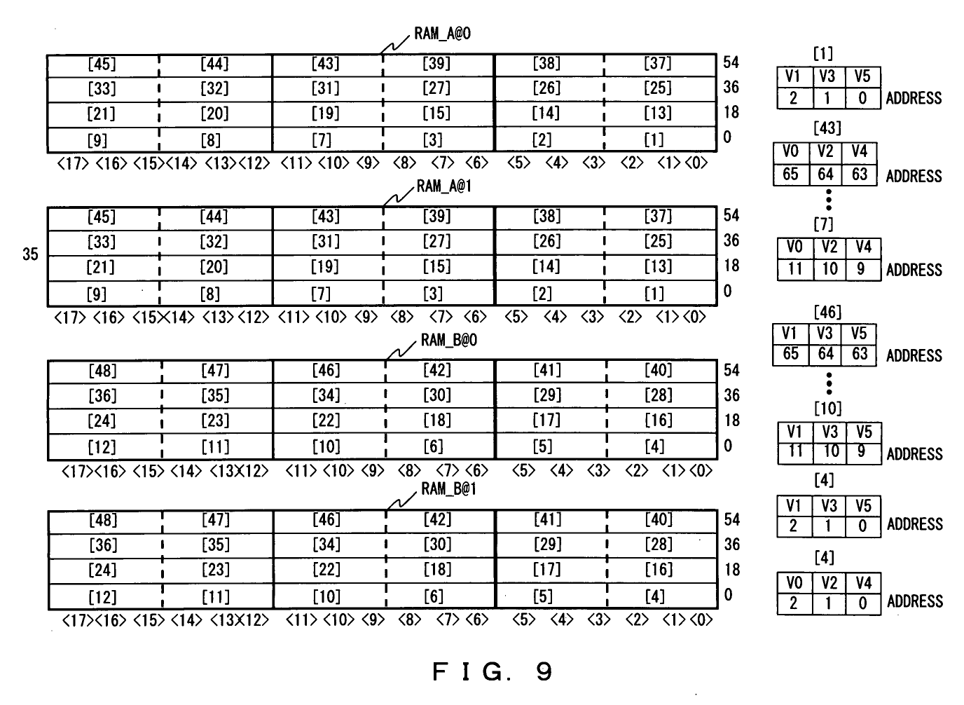

FIG. 9 illustrates data structures stored by the above described RAM_A@0 and RAM_A@1, and RAM_B@0 and RAM_B@1. The values within the “<>” noted under the RAM_A@1 and RAM_B@0 are the column numbers, and the values 0, 18, 36 and 54 written on the right side of each RAM are addresses of the column <0>. Note that the correlation between the column numbers and the [1] [2] [3] [7] [8] [9] and so on, which store data, as shown by FIG. 9, is different from that of FIGS. 7 and 8; FIGS. 7 through 9, however, are for illustrating the data structure and the correspondence of the column numbers <0> to <17> of FIG. 7 and FIG. 8 are different from that of FIG. 9.

Defining the address of the line 0, column 0 as “0”, that of the line 0, column 1 as “1” and that of the line 0, column 2 as “2”, of the RAM_A and RAM_B both shown by FIG. 9, the addresses 0 through 2 of the RAM_A@0 store 3-bit data V5, V3 and V1 of the data [1] of a unit 1 (NB: “unit” is described later associated with FIG. 14), and the addresses 0 through 2 of the RAM_A@1 store the remaining 3-bit data V4, V2 and V0 of the data [1]. And the addresses 3 through 5 of the RAM_A@0 store 3-bit data V5, V3 and V1 of the data [2], and the addresses 3 through 5 of the RAM_A@1 store the remaining 3-bit data V4, V2 and V0 of the data [2].

Likewise, the addresses 9 through 11 of the RAM_A@0 store 3-bit data V5, V3 and V1 of the data [7], and the addresses 9 through 11 of the RAM_A@1 store the remaining 3-bit data V4, V2 and V0 of the data [7].

Similarly to the above description for the following, the addresses 63 through 65 of the RAM_A@0 store 3-bit data V5, V3 and V1 of the last data [43] of the same unit 1, and the addresses 63 through 65 of the RAM_A@1 store the 3-bit data V4, V2 and V0 of the last data [43] of the same unit 1 as shown by the dotted lines on the right side (viewed from the front) of FIG. 9.

The RAM_A@0 and RAM_A@1 store the respective data [1], [2], [3], [7], [8], [9] and so on, among the data [1] through [48] shown by FIG. 7A.

Likewise for the RAM_B@0 and RAM_B@1, in which the addresses 0 through 2 of the RAM_B@0 store 3-bit data V5, V3 and V1 of the data [4], and the addresses 0 through 2 of the RAM_B@1 store the remaining 3-bit data V4, V2 and V0 of the data [4].

Therefore, the RAM_B@0 and RAM_B@1 store the respective data [4], [5], [6], [10], [11], [12 ] and so on among the data [1] through [48] shown by FIG. 7A.

The structures of data stored by the RAM_A@0, RAM_A@1, RAM_B@0 and RAM_B@1 which are shown by FIG. 9 are laid out in a line in the RAM_A and RAM_B which are shown by FIG. 7B, or the RAM_A@0, RAM_A@1, RAM_B@0 and RAM_B@1 which are shown by FIG. 7C.

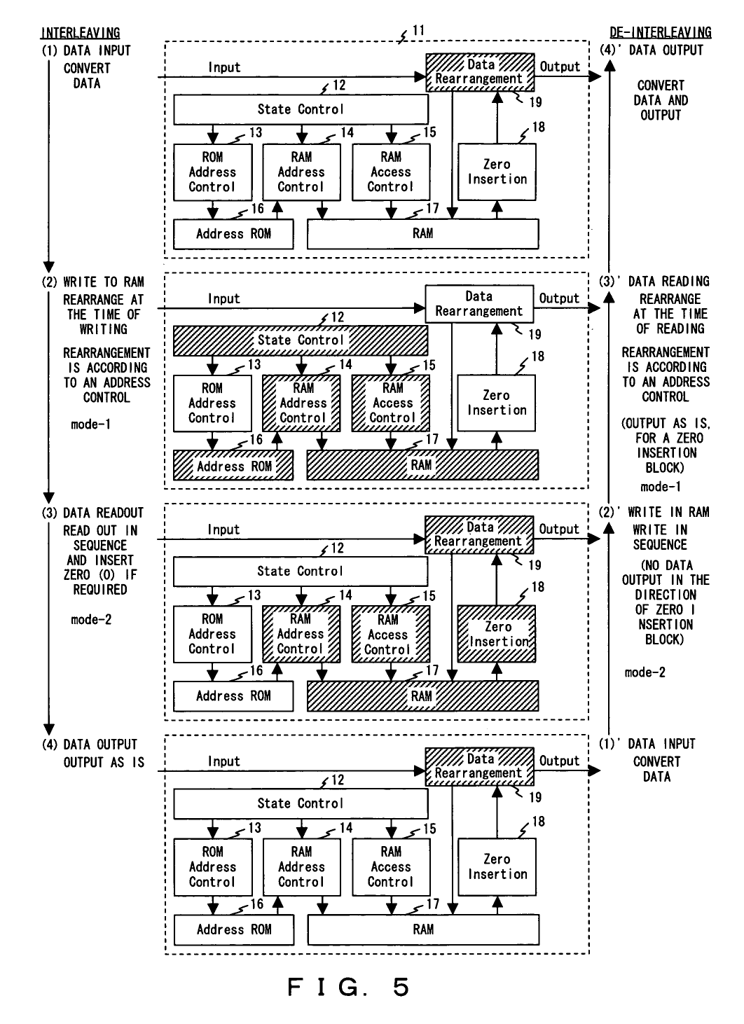

The next description is of an outline of an operation of the interleaving and de-interleaving processing unit 11 as shown by FIGS. 3 and 4 by referring to FIG. 5. Note that the blocks with oblique line shown by FIG. 5 relate to the operation of the respective steps (1) through (4), and (1)′ through (4)′ shown by FIG. 5.

At the time of an interleaving, the data rearrangement unit 19 converts input data to 2-bit parallel data (refer to the step (1) in FIG. 5).

At the time of an interleaving, the state control 12 outputs mode-1 state information (i.e. a state1 shown by FIG. 4) for the purpose of writing data to the RAM 17 by rearranging the data, and mode-2 state information (i.e. a state2 shown by FIG. 4) for reading out data, as is, written to the RAM 17.

The ROM address control 13 controls a readout address of the address ROM 16 based on the state information output from the state control 12, and the RAM address control 14 specifies a write and a readout address of the RAM 17 based on the address data which is read out of the address ROM 16. Furthermore, the RAM access control 15 selects a RAM 17 as the access target based on the state information state1 and the state information state2 (the step (2) of FIG. 5)

As the RAM address control 14 specifies the address for rearranging data and the RAM access control 15 selects the RAM 17 as the access target, data is sequentially written in addresses of the specified line and column, or data is sequentially read out of the addresses of the specified line and column, thereby rearranging the data. Meanwhile, if there is a need to insert “0” in the read data out of the RAM 17, the zero insertion circuit 18 inserts “0” into a specific bit and outputs to the data rearrangement unit 19 (the step (3) of FIG. 5).

The data rearrangement unit 19 outputs data output from the zero insertion circuit 18, as is, in an interleaving processing (the step (4) of FIG. 5).

The next description is of an operation of a de-interleaving processing. At the time of a de-interleaving, the data rearrangement unit 19 converts input data to 2-bit parallel data (the step (1)′ of FIG. 5). Then the converted data is sequentially written to the RAM 17 (the step (2)′ of FIG. 5). In this event, the data is not output to the zero insertion circuit 18.

Rearrangement of data is carried out at the time of reading the data. For an rearrangement of data, the ROM address control 13 controls a readout address of the address ROM 16 based on the mode-1 state information output from the state control 12, and the RAM address control 14 specifies a write and a readout address based on the state information state1 and state2 and the address data read out of the address ROM 16. Then, the RAM access control 15 selects a RAM 17 as the access target based on the state information state1 and state2.

As the RAM address control 14 specifies the address for the purpose of rearranging data and the RAM access control 15 selects the RAM 17 as the access target, then the data is read out of the address of the specified line and column of the RAM 17 in a prescribed sequence and the data is rearranged, followed by outputting the readout data to the zero insertion circuit 18 which then outputs the data output from the RAM 17 to the data rearrangement unit 19 as is (the step (3)′ of FIG. 5).

The data rearrangement unit 19 converts the data which is read out of the RAM 17 matching a data format for a circuit on the output side (the step (4)′ of FIG. 5).

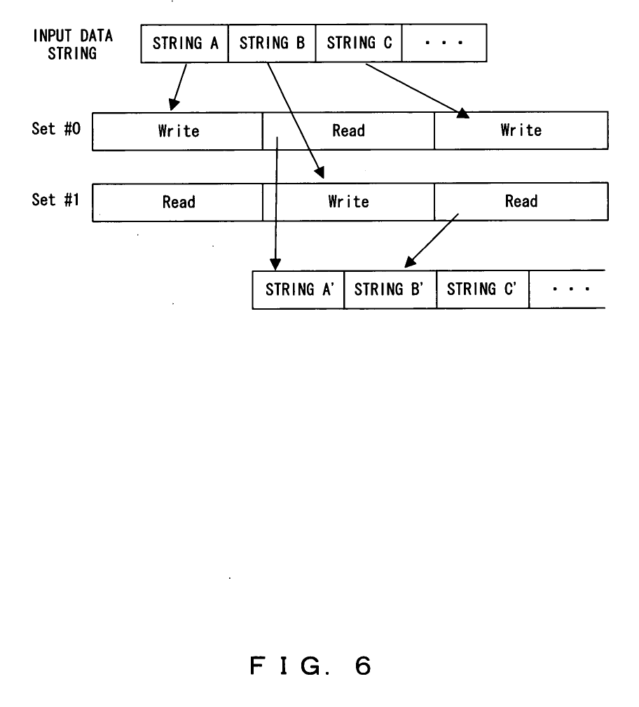

FIG. 6 shows a write operation for input data strings A, B, C, and so on, and readout operation for the strings A′, B′ and C′ for two sets of RAM (i.e., the set #0 and the set #1). The set #0 and the set #1 respectively mean one set of RAM. For example, one set of RAM configured with @=0 of four RAM (i.e., RAM_A@0, RAM_A@1, RAM_B@0 and RAM_B@1) are defined as the set #0, while one set of RAM configured with @=1 are defined as the set #1.

In the case of carrying out an interleaving for an input data string, the input data is rearranged according to the mode-1 state information, followed by writing in the specified RAM among the RAM in the set #0. That is, the data is rearranged by writing the initial input data string A to an address specified by the RAM address control 14 of a RAM selected by the RAM access control 15.

Then, an input data string B is written to an address specified by the RAM address control 14 of a RAM selected by the RAM access control 15 among the RAM in the set #1. Simultaneously with this event, a data string A′, is readout of an address specified by the RAM address control 14 of a RAM selected by the RAM access control 15 according to the mode-2 state information, and is rearranged. This is followed by a data write and a readout being carried out in parallel by the same procedure. Referring to FIG. 5, note that although only one of the mode-1 and mode-2 seems to operate by switching over, the actual fact is that when one set of RAM (e.g., the set #0) is in the mode-1, the other one set of RAM (i.e., the set #1) is operated in the mode-2 and therefore, when one set of RAM change over from the mode-1 to mode-2 for operation, the other set thereof also changes over from the mode-2 to mode-1 for operation. Such use of two sets of RAM enables the mode-1 and the mode-2 simultaneously.

In the case of a de-interleaving, the operation is the reverse of the above described in which an input data string is written, as is, in a specified RAM among the RAM of the set #0 according to the mode-2 state information, followed by writing data, as is, in a specified RAM among the RAM of the set #1 according to the mode-2 state information and at the same time reading data out of a specified address of a specified RAM of the RAM of the set #0 according to the mode-1 state information, thereby rearranging the data.

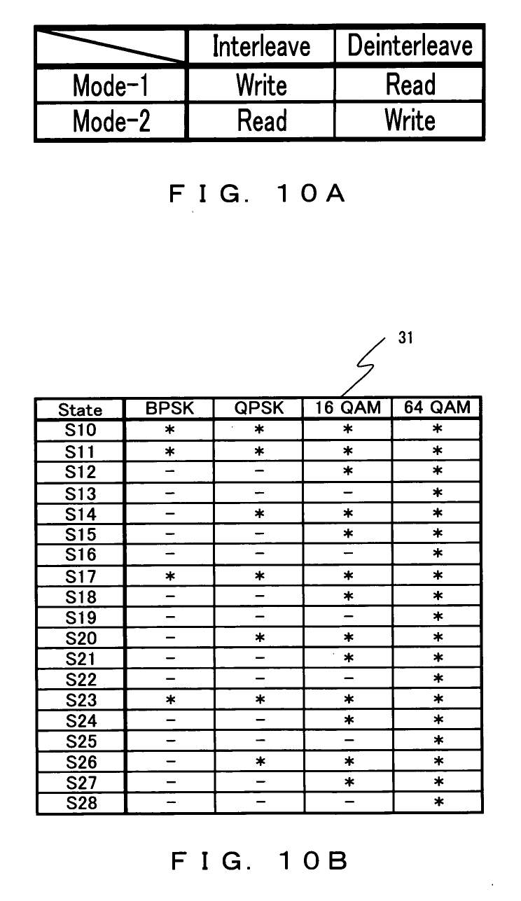

Next, FIG. 10A shows an operating mode of the state control 12.

The state control 12 outputs the mode-1 state information state1 (refer to FIG. 4), rearranges input data and writes to the RAM 17 and at the same time reads the rearranged data out of the RAM 17 by outputting the mode-2 state information state2 (refer to FIG. 4) at the time of an interleaving as shown by FIG. 10A. And the state control 12, while writing input data to the RAM 17 as is by outputting the mode-2 state information state2 and at the same time reading data out of the RAM 17 by outputting the mode-1 state information state1, carries out a control for making a data rearranged at the time of a de-interleaving.

Outputs of the mode-1 state information state1 and mode-2 state information state2 are carried out by the mode-1 state control 21 and mode-2 state control 22 comprised by the state control 12 according to the timing signal tmg1 and timing signal tmg2 which are synchronized with the data.

FIG. 10B shows a correlation table 31 for making state information state1, which is output from the state control 12 for the purpose of making an operation of a mode-1 performed, correlated with the modulation systems.

The state control 12 identifies a modulation system from a rate signal and outputs state information indicated by the correlation table 31 shown by FIG. 10B.

In the case of a BPSK modulation for example, the state control 12 sequentially outputs four kinds of state information, i.e., states S10, S11, S17 and S23.

In the case of a QPSK modulation, the state control 12 first outputs states for the case of a BPSK modulation, followed by outputting the respective pieces of state information of states S11, S14, S17, S20, S23 and S26 repeatedly and sequentially (NB: since the BPSK modulated header is read, the state information of states S10, S11, S17 and S23 are first readout, followed by outputting state information matching with the respective modulation of the data parts repeatedly.)

In the case of a 16 QAM modulation, states for the case of BPSK are outputted first, followed by outputting the respective pieces of state information of states S11, S12, S14, S15, S17, S18, S20, S21, S23, S24, S26 and S27 sequentially and repeatedly.

In the case of a 64 QAM modulation, the state for the case of the BPSK modulation is output, followed by outputting the respective pieces of state information of states S11 through S28 sequentially and repeatedly.

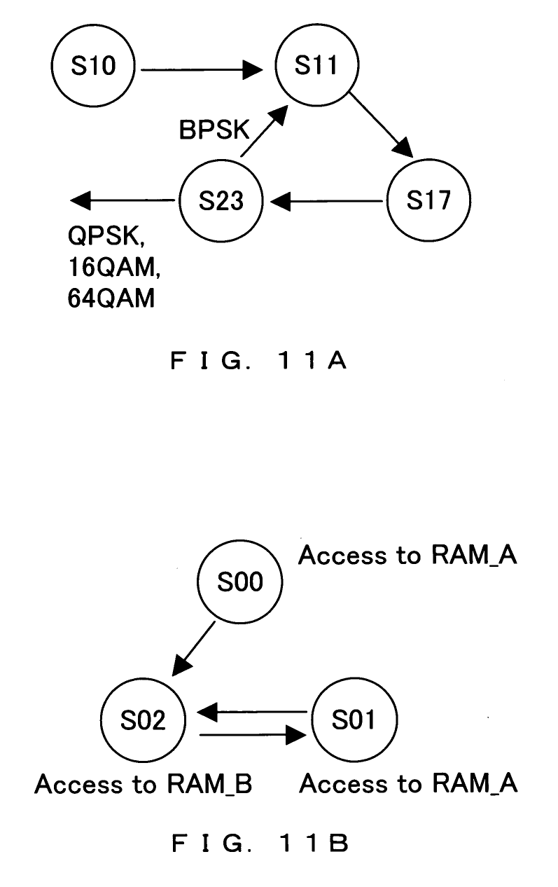

FIG. 11A shows a transition of mode-1 state information in the case of a modulation system being a BPSK.

In the case of the BPSK modulation, a state S10 is first outputted for making an initial state established, followed by outputting states S11, S17 and S23 sequentially. Then, the state S11 is output again, followed by sequentially outputting states S11, S17 and S23 repeatedly. In the cases of the QPSK modulation, 16 QAM modulation and 64 QAM modulation, the header part is the BPSK modulation with the data part being the QPSK modulation, 16 QAM modulation and 64 QAM modulation, respectively, and therefore the state S10 is output for causing the initial state to be established, followed by outputting the states S11, S17 and S23, sequentially and followed by changing to the states matching the QPSK modulation, 16 QAM modulation and 64 QAM modulation, respectively.

FIG. 11B shows a transition of mode-2 state information.

In the mode-2, the same state information is output independent of a modulation system, a state S00 for the purpose of accessing the RAM_A first in order to establish an initial state, followed by outputting a state S02 for the purpose of accessing the RAM_B, further followed by alternately outputting a state S01 for the purpose of accessing the RAM_A and state S02 for the purpose of accessing the RAM_B.

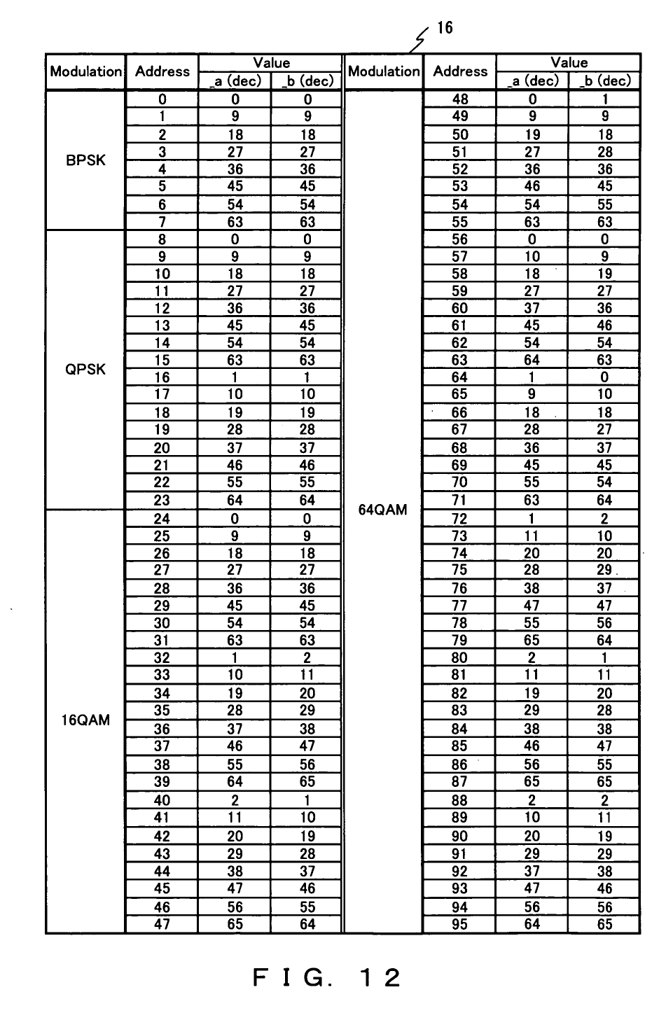

Next, FIG. 12 shows a data structure of the address ROM 16 which operates based on the mode-1 state information when carrying out an interleaving and de-interleaving and does not operate in a mode-2. The address ROM 16 stores address data for the purpose of specifying an address of the RAM_A and RAM_B (i.e., the RAM 17) corresponding to each modulation system. The_Address shown by FIG. 12 indicates a readout address, of the address ROM 16, which is output from the ROM address control 13, the a (dec) shows address data for the purpose of specifying an address of the RAM_A,. the _b (dec) shows address data for the purpose of specifying an address of the RAM_B, and the dec signifies a decimal number. An addition of the address data, which is output from the address ROM 16, of the RAM_A and RAM_B, and a predefined unit offset (i.e., the offset addresses of the unit 1 through 3 are equal to the unit offset address) specifies the final addresses of the RAM_A and RAM_B. The “unit offset” is described later in association with FIG. 14.

The addresses 0 through 7 of the address ROM 16, store the address data of the RAM_A and RAM_B in the case of the BPSK modulation.

The addresses 8 through 23 store the address data of the RAM_A and RAM_B in the case of the QPSK modulation.

The addresses 24 through 47 store the address data of the RAM_A and RAM_B in the case of the 16 QAM modulation.

Furthermore, the addresses 48 through 95 store the address data of the RAM_A and RAM_B in the case of the 64 QAM modulation.

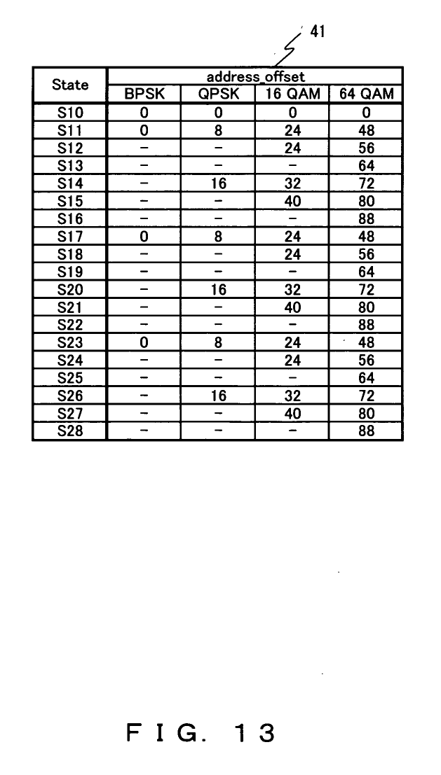

Next, FIG. 13 shows an address offset table 41 of the ROM address control 13 correlating state information and a readout address of the address ROM 16 of each modulation system. The ROM address control 13 operates according to the mode-1 state information at the time of an interleaving and de-interleaving and does not operate in a mode-2.

The offset control 24 (refer to FIG. 4) comprised in the ROM address control 13 outputs, to the adder 25, an address offset (which is a value determined corresponding to each state information) shown by the address offset table 41 shown by FIG. 13 based on a modulation system and the mode-1 state information state1.

The adder 25 adds the above described address offset to the base address of 0 through 7 which are output from a base address control 23 and outputs the addition result as the readout address rom_addr (refer to FIG. 4) of the address ROM 16. An addition of a base address counted by circulating from 0 to 7 and an address offset eliminates a necessity of the address offset table 41 retaining all readout addresses, thereby enabling a reduction of a memory size thereof.

For example, in the mode-1 state S11 of the 64 QAM modulation, the ROM address control 13 sequentially outputs, to the address ROM 16, eight addresses, i.e., 48 through 55, as the results of the address offset “48” of the state S11 added to the base addresses 0 through 7.

By such a process, read out sequentially are eight sets of address data (value: _a, _b) (0, 1) (9, 9) (19, 18) (27, 28) (36, 36) (46, 45) (54, 55) and (63, 63) of the RAM_A and RAM_B, which are stored by the addresses 48 through 55 of the address ROM 16 shown by FIG. 12.

Likewise, in the state S12 of the 64 QAM modulation, the ROM address control 13 sequentially outputs eight addresses, i.e., 56 through 63, as the results of the address offset “56” shown by FIG. 13 added to the base addresses 0 through 7. By such a process, eight sets of address data of the RAM_A and RAM_B are read out of the addresses 56 through 63 of the address ROM 16 shown by FIG. 12.

Next, FIG. 14A shows a unit offset table 51 used by the RAM address control 14. And FIG. 14B describes a control method for an access position of the RAM 17 by a unit offset. The unit offset is defined as a necessary offset value in order to write or read data per unit having a certain interval when writing data to, or reading out of, the RAM_A and RAM_B which constitute the RAM 17. For example, accessing data [1] [4] [7] [10] through [43] and [46] of the unit 1 (i.e., the unit offset is equal to 0 (zero)) shown by FIG. 14B means accessing data [1] [4] [7] [10] through [43] and [46] of the columns 0 through 5 (i.e., <0> through <5>) of a data structure illustrated by FIG. 7A. Likewise, accessing data [2] [5] [8] [11] through [44] and [47] of the unit 2 (i.e., the unit offset is equal to 3) shown by FIG. 14B means accessing data [2] [5] [8] [11] through [44] and [47] of the columns 6 through 11 (i.e., <6> through <11>) of the data structure illustrated by FIG. 7A.

The RAM address control 14 outputs the respective addresses addr_a1 and addr_b1 of the RAM_A and RAM_B for the mode-1, and, at the same time, the respective addresses addr_a2 and addr_b2 thereof in the mode-2 at the time of an interleaving and de-interleaving processing.

The mode-1 address control 26 shown by FIG. 4 adds either of three kinds of unit offsets [0], [3] and [6] of the unit offset address table 51 shown by FIG. 14A to the address data output from the address ROM 16 according to state information, and outputs the addition result as the respective addresses addr_a1 and addr_b1 of the RAM_A and RAM_B for the mode-1. FIG. 14A denotes an addition of a unit offset of 0 (zero) in the state S11, that of a unit offset of 3 in the state S17, that of a unit offset of 6 in the state S23 and retaining the value of the unit offset prior to the current state in a state other than the aforementioned states. For example, in the 64 QAM modulation, when the state S11 transits to the next state S12, the unit offset stays unchanged at 0 (zero), while as the state transits to the state S17 the unit offset becomes 3 (three)

The mode-2 address control 27 outputs the respective addresses addr_a2 and addr_b2 of the RAM_A and RAM_B for the mode-2 according to the state information state2 and a timing signal tmg2.

Outputting the addresses added by the unit offset as described above to the RAM_A and RAM_B makes it possible to access the data thereof at a certain address interval as shown by FIG. 14B. The units 1, 2 and 3 correspond to the respective accesses of <0> through <5>, <6> through <11>, and <12> through <17> for the RAM 17 shown by FIG. 7A.

The case of carrying out a de-interleaving processing of the 64 QAM modulation reads out a certain number of data of the column numbers <0> through <5> in the RAM 17 shown by FIG. 7A by specifying the addresses of the RAM_A and RAM_B by respectively adding a unit offset “0” for the unit 1 to the address data output from the address ROM 16, then reads out a certain number of data of the column numbers <6> through <11> by specifying the addresses of the RAM_A and RAM_B by respectively adding a unit offset “3” for the unit 2, then reads out a certain number of data of the column numbers <12> through <17> by specifying the addresses of the RAM_A and RAM_B by respectively adding a unit offset “6” for the unit 3, thereby making it possible to restore the data rearranged according to the arrangement rule of the 64 QAM modulation to the original order.

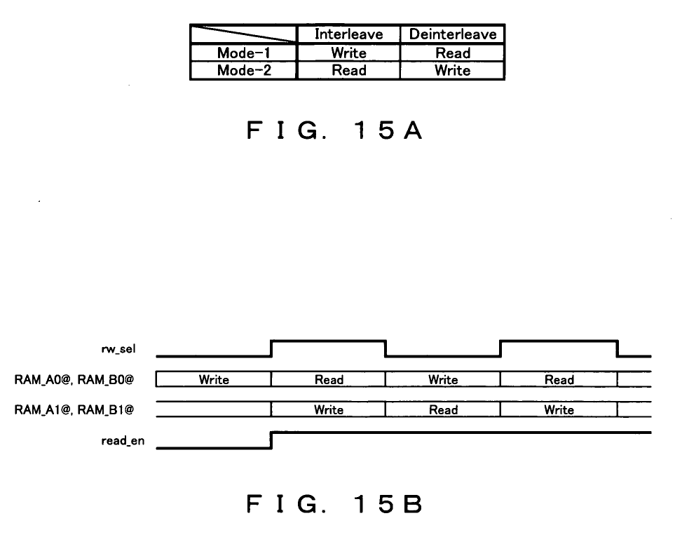

Next, FIG. 15A shows an operating condition of the RAM access control 15. As shown by FIG. 15A, the RAM access control 15 operates so as to write data to the RAM_A and RAM_B in the mode-1, and read data out thereof in the mode-2 at the time of an interleaving. And operates so as to read data out of the RAM_A and RAM_B in the mode-1 and write data thereto in the mode-2 at the time of a de-interleaving.

FIG. 15B shows an access operation for the RAM_A and RAM_B. The lower level (i.e., a fall state) of the rectangular wave of a selection signal rw_sel shown by FIG. 15B indicates zero (0), while the upper level (i.e., a rise state) indicates one (1). The lower level (i.e., a fall state) of the rectangular wave of a read enable signal read_en indicates zero (0), while the upper level (i.e., a rise state) indicates one (1).

One (i.e., RAM of the set #0 comprising the RAM_A0@ and RAM_B0@) of the two sets of the RAM_A0@ and RAM_A1@, and RAM_B0@ and RAM_B1@, assumes a write state when the selection signal rw_sel is “0”, while assuming a readout state when the rw_sel is “1”; and the other (i.e., RAM of the set #1 comprising the RAM_A1@and RAM_B1@) assumes a write state when the selection signal rw_sel is “1”, while assuming a readout state when the rw_sel is “0”. That is, the operation is such that as the RAM of the set #0 are read, the RAM of the set #1 are written to at the same time, or as the set #0 is written to, the set #1 is read out at the same time.

When the read enable signal read_en is “1”, the RAM_A and RAM_B are enabled for reading out. The read enable signal is set to “0” in an initial state, that is, the mode is set for not reading out, in order to start from a data write.

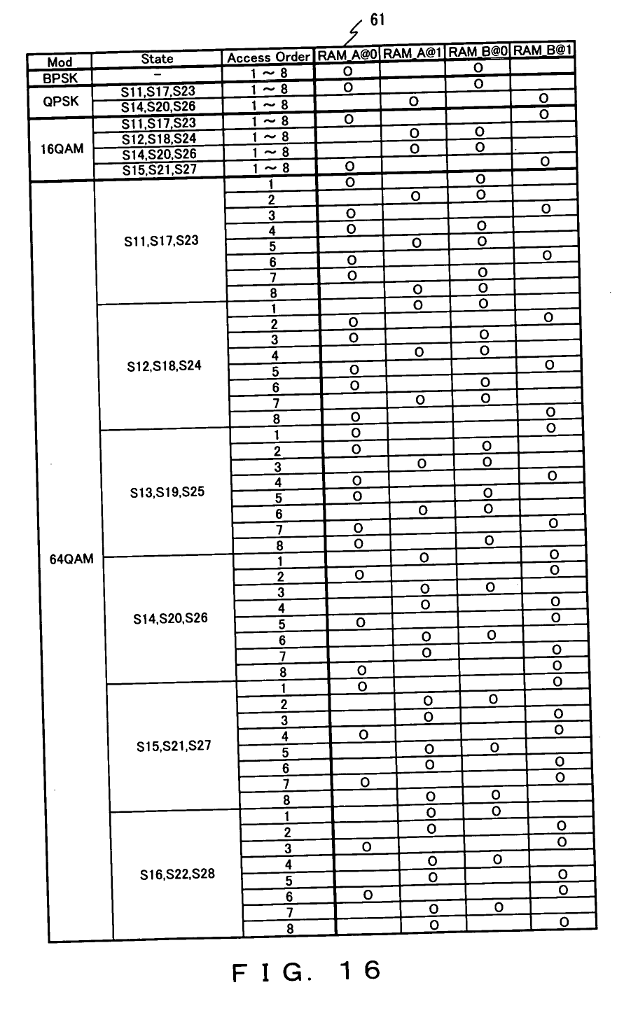

Next, FIG. 16 shows a RAM selection table 61 for indicating a selecting operation of the RAM access control 15 in the mode-1. The “state” shown by FIG. 16 indicates state information, and the “access order” shows a transition of a selection state (i.e., an order of access) for selecting which RAM among the RAM 17 to write to. An increase in the base address is related to that of the access order, with an increase of one access order increasing the base address by one. That is, as the access order changes to cause a selection signal of the RAM 17 output from the RAM access control 15 to change, the base address also changes, causing a write and a readout address of the RAM 17 which are output from the RAM address control 14 to change, thereby selecting a specific address of a RAM as the access target.

The RAM selection table 61 correlates the selection signals (indicated by “o” in FIG. 16) of the RAM_A@0, RAM_A@1, RAM_B@0 and RAM_B@1 with the state information of each modulation method.

For example, in the case of the 64 QAM modulation with state information state1 being in the state S11, a signal for selecting the RAM_A@0 and RAM_B@0 is output at the time of an access order 1, while a signal for selecting the RAM_A@1 and RAM_B@0 is output at the next access order 2.

Next, let a readout operation, at the time of a de-interleaving processing, of the interleaving and de-interleaving processing unit 11 which is configured as described above be described, by referring to FIGS. 12, 13, 14, 16, and 17. A write operation at the time of an interleaving processing is also the same.

In the mode-1 of a de-interleaving, as the state control 12 outputs a state S12 as state information state1, the ROM address control 13 outputs, to the address ROM 16, an address “48”, which is an addition of the address offset “48” corresponding to the state S11 of the address offset table 41 shown by FIG. 13, and the initial value “0” of the base address.

By such a process, the address ROM 16 outputs the address data “0” of the RAM_A and the address data “1” of the RAM_B which are stored in the address “48” of the 64 QAM modulation shown by FIG. 12.

Here, since the unit offset of the unit 1 is “0” (i.e., referring to the unit offset table 51 shown by FIG. 14, the unit offset for the state S11 is “0”), the RAM address control 14 outputs the address data “0” of the RAM_A and the address data “1” of the RAM_B, as is, which are output from the address ROM 16, to the RAM_A and RAM_B.

At the same time, the RAM access control 15 outputs a signal for selecting the RAM_A@0 and RAM_B@0 as a signal for selecting the RAM 17 for the state S11 of the 64 QAM modulation (refer to the RAM selection table 61 shown by FIG. 16).

Therefore, in reading out the first data of the unit 1 for the state S11, the data of the address “0” of the RAM_A@0 and the address “1” of the RAM_B@0 are read out simultaneously. The address “0” of the RAM_A@0 is the zeroth bit of the data [1] position of the RAM_A@0 shown by FIG. 9 and the data at the position is V5. And the address “1” of the RAM_B@0 is the first bit of the data [4] position of the RAM_B@0 shown by FIG. 9 and the data at the position is V3.

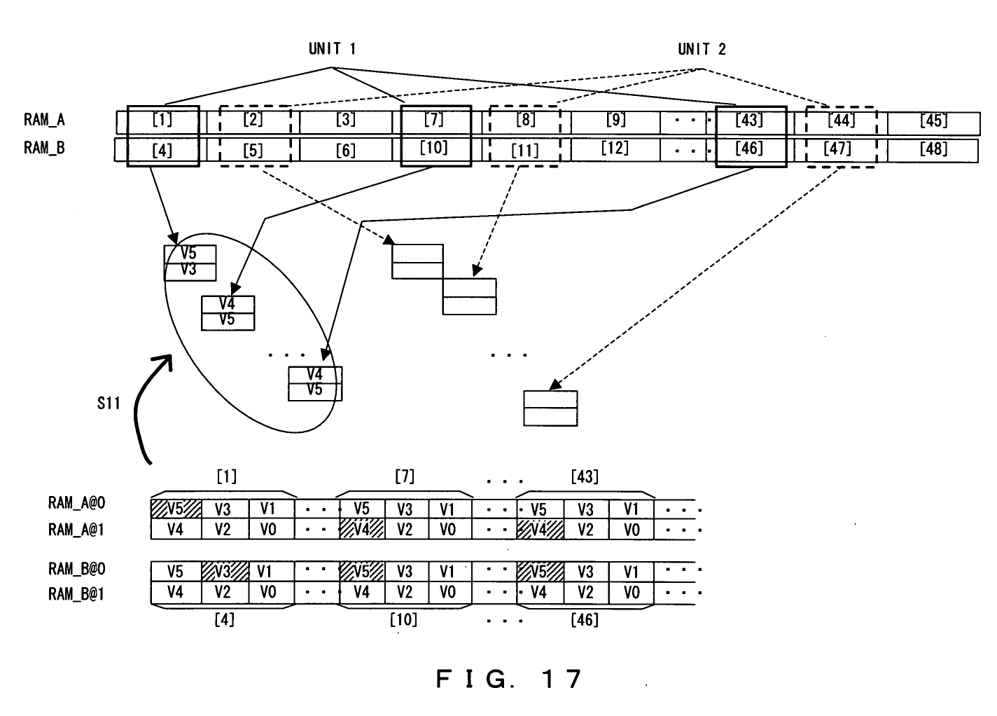

Therefore, the first readout data of the unit 1 are V5 and V3 as shown by FIG. 17 in the state S11 of the mode-1 of a de-interleaving.

After a predetermined time passes (e.g., a period determined by a timing signal tmg2), the ROM address control 13 outputs, to the address ROM 16, the address “49” which is an addition of the address offset “48” and the next value “1” of the base address.

By such a process, the address ROM 16 outputs the address data “9” of the RAM_A and the address data “9” of the RAM_B which are stored in the address “49” of the 64 QAM modulation shown by FIG. 12.

Since the unit offset in this case is “0”, the RAM address control 14 outputs the address “9” of the RAM_A and the address “9” of the RAM_B, as is, which are output from the address ROM 16, to the RAM_A and RAM_B.

At the same time, the RAM access control 15 outputs a selection signal for selecting the RAM_A@1 and RAM_B@0 of the access order 2 (i.e., the second of the unit 1, i.e., [7] and [10]) for the state S11 of the 64 QAM modulation which is shown by the RAM selection table 61 of FIG. 16.

Therefore, in the second readout of the unit 1 for the state S11, the data of the address “9” of the RAM_A@L and that of the address “9” of the RAM_B@0 are read out simultaneously.

The address “9” of the RAM_A@1 indicates the zeroth bit of the data [7] position of the RAM_A@1 shown by FIG. 9, and the zeroth bit data is V4. And the address “9” of the RAM_B@0 indicates the zeroth bit of the data [10] position of the RAM_B@0 shown by FIG. 9, and the zeroth bit data is V5.

Accordingly, the second readout data of the unit 1 are V4 and V5 as shown by FIG. 17 in the state S11 of the de-interleaving.

The data readouts from the third data (i.e., [13] and [16]) through the seventh data (i.e., [37] and [40]) of the unit 1 are completed in the same manner, and the ROM address control 13 outputs a value “55”, which is an addition of the address offset “48” and the maximum value “7” of a base address, in order to read out the eighth data (i.e., [43] and [46]) of the unit 1.

In such a way, the address ROM 16 outputs the address data “63” of the RAM_A and the address data “63” of the RAM_B which are stored in the address 55 position of the 64 QAM modulation.

Also in this event, since the unit offset is “0”, the RAM address control 14 outputs the address “63” of the RAM_A and the address “63” of the RAM_B, as is.

At the same time, the RAM access control 15 outputs a selection signal for selecting the RAM_A@1 and RAM_B@0 (refer to FIG. 16).

Therefore, in the eighth readout of the unit 1 for the state S11, the data of the address “63” of the RAM_A@1 and that of the address “63” of the RAM_B@0 are read out simultaneously. The address “63” of the RAM_A@1 indicates the zeroth bit of the data [43] position of the RAM_A@1 shown by FIG. 9, and the zeroth bit data is V4. And the address “63” of the RAM_B@0 indicates the zeroth bit of the data [46] position of the RAM_B@0 shown by FIG. 9, and the zeroth bit data is V5.

Accordingly, the eighth readout data of the unit 1 are V4 and V5 as shown by FIG. 17 in the state S11 of the de-interleaving.

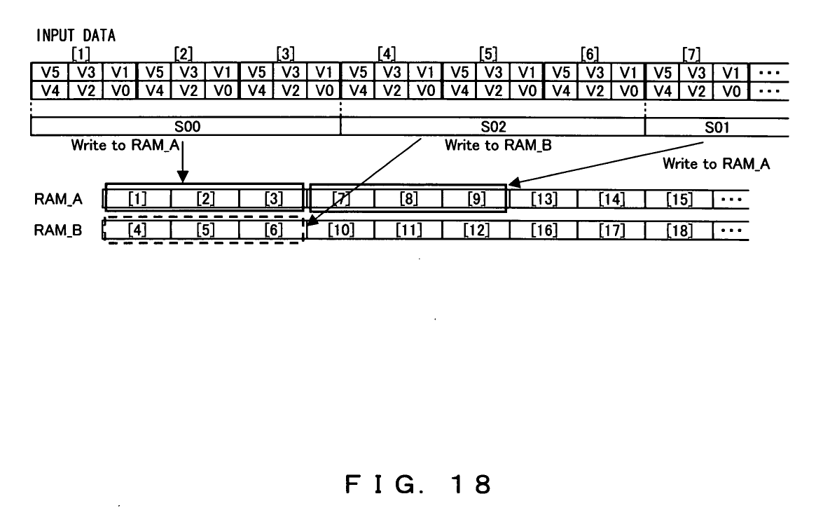

FIG. 18 describes a write operation in the mode-2 of a de-interleaving processing of the 64 QAM modulation. The readout processing at the time of an interleaving processing is also the same.

A data write in the mode-2 at the time of a de-interleaving only writes input data, which is rearranged, in the RAM_A and RAM_B without rearranging the sequence.

The state control 12 first outputs the state S00 as the mode-2 state information, and the input data [1], [2] and [3] are written to the RAM_A. And the state control 12 then outputs the state S02, and the input data [4], [5] and [6] are written to the RAM_B. The state control 12 then outputs the state S01, and the input data [7], [8] and [9] are written to the RAM_A. This is followed by the state control 12 outputting the states S02 and S01 alternately, and the data is written to the RAM_A and the RAM_B alternately.

As described above, at the time of carrying out an interleaving or de-interleaving processing, the state control 12 outputs the mode-1 and mode-2 state information of each modulation system (e.g., the states S11 through S28 in the mode-1, and the states S00 through S02 in the mode-2, of the 64 QAM modulation), and address data of the address specified by the state information of each modulation system is read out of the address ROM 16. Then, respective addresses of the RAM_A and RAM_B are specified based on the address data, and data are written to the specified addresses or read out thereof, thereby enabling the data to be rearranged in the prescribed sequence. That is, an interleaving processing and a de-interleaving processing are accomplished by a common use of the interleaving and de-interleaving processing unit 11.

For example, in a de-interleaving processing of the 64 QAM modulation, reading the first through eighth data (i.e., [1] [4] through [43] and [46]) of the unit 1, through eighth data (i.e., [2] [5] through [44] and [47]) of the unit 2, and through eighth data (i.e., [3] [6] through [45] and [48]) of the unit 3, out of the RAM_A and RAM_B, based on the addresses outputted from RAM address control 14, thereby enabling interleaved input data to be restored to the original sequence.

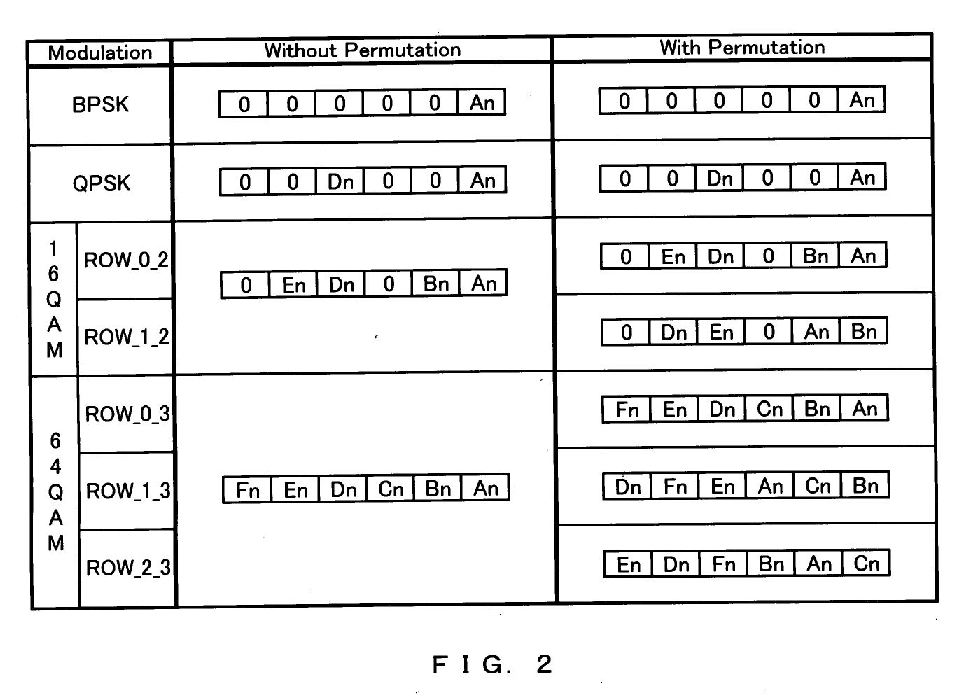

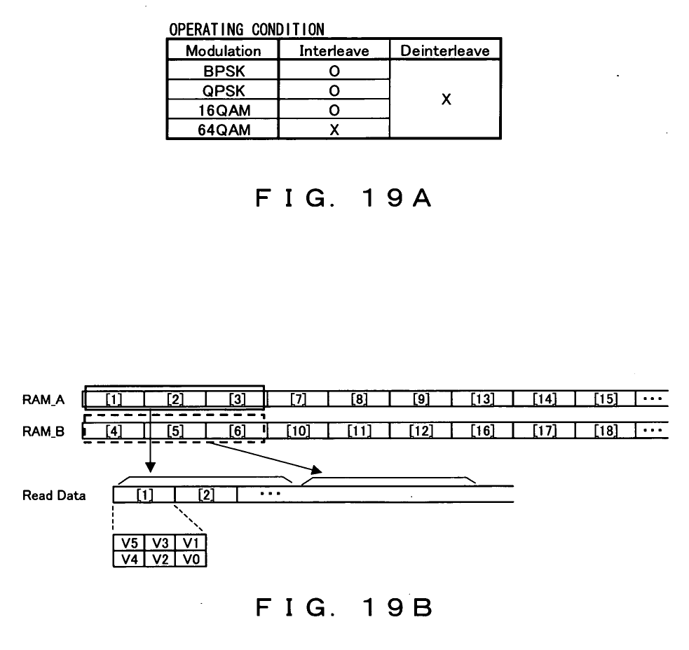

Next, FIG. 19A shows an operating condition of the zero insertion circuit 18. In the case of rearranging data according to the data rearrangement rule shown by FIG. 2 at the time of an interleaving, it is necessary to write zero (0) in a part other than data to be rearranged. For this reason, the zero insertion circuit 18 inserts zero (0) in positions (i.e., the positions indicated by “0” as shown by FIG. 2) other than the positions where primary data is written according to the specification of the rearrangement rule of each modulation system shown by FIG. 2. Specifically, at the time of an interleaving of the BPSK modulation, QPSK modulation and 16 QAM modulation, the zero insertion circuit 18 outputs data with “0” inserted in the positions indicated by “0” in FIG. 2 for the data read out of the RAM 17. In the case of the 64 QAM modulation, there is no need to insert zero (0) and accordingly the data read out of the RAM 17 is output as is. At the time of de-interleaving, data read out of the RAM 17 is output as is.

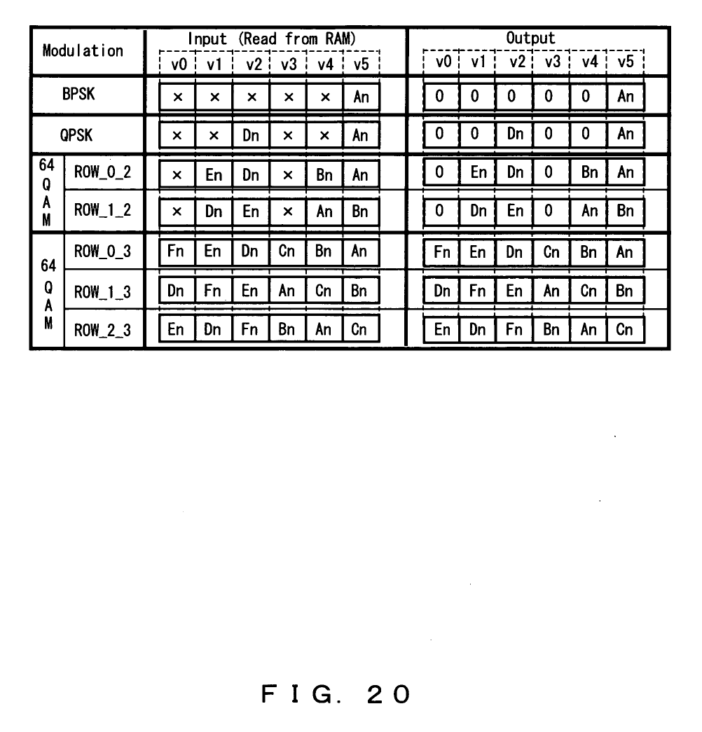

Next, FIG. 20 shows data (i.e., input) read out of the RAM_A and RAM_B (i.e., a RAM 17) and data (i.e., output) output from the zero insertion circuit 18.

As shown by the Input on the left side of FIG. 20, as for interleaved data of the BPSK modulation, QPSK modulation and 16 QAM modulation, data other than targeted data (i.e., data indicated by An, Bn, and so on, in FIG. 20) is indeterminate (e.g., the “x” positions where V0 through V4 data do not exist in the case of the BPSK modulation shown by FIG. 20).

For example, in the BPSK modulation, data other than V5 in the zeroth bit position is indeterminate, “0” as data of V4 through V0 in the position of the first bit through fifth bit is inserted.

Likewise in other modulation systems, the zero insertion circuit 18 inserts “0” in the position of data other than the data as the rearrangement target.

As a result, the zero insertion circuit 18 outputs, to the data rearrangement unit 19, data with “0” inserted in the applicable position of the data which has been interleaved by each modulation method as shown by the output on the right side of FIG. 20.

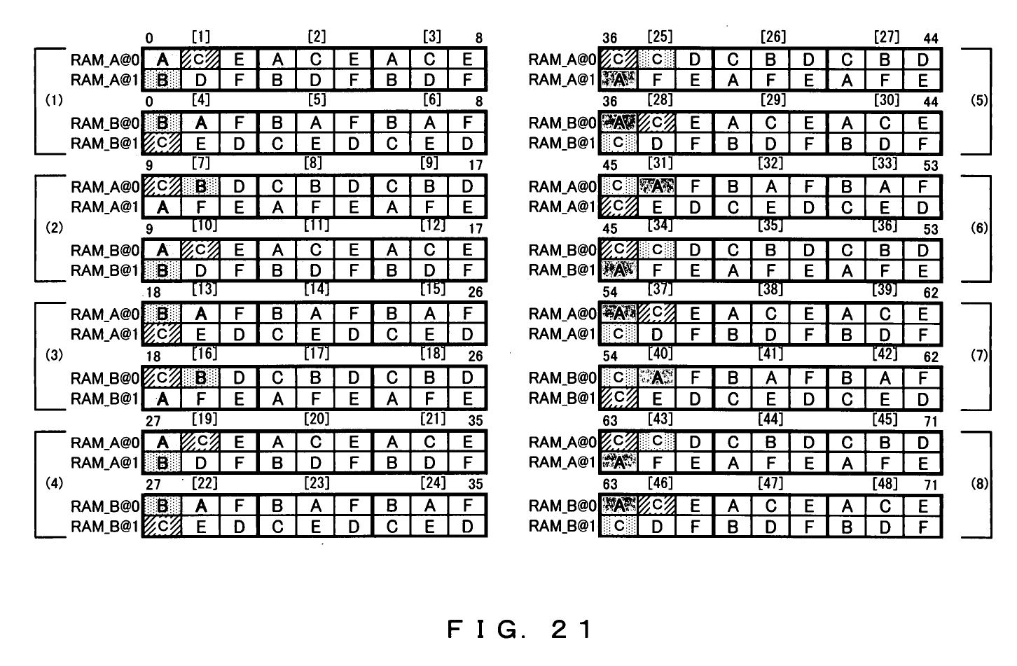

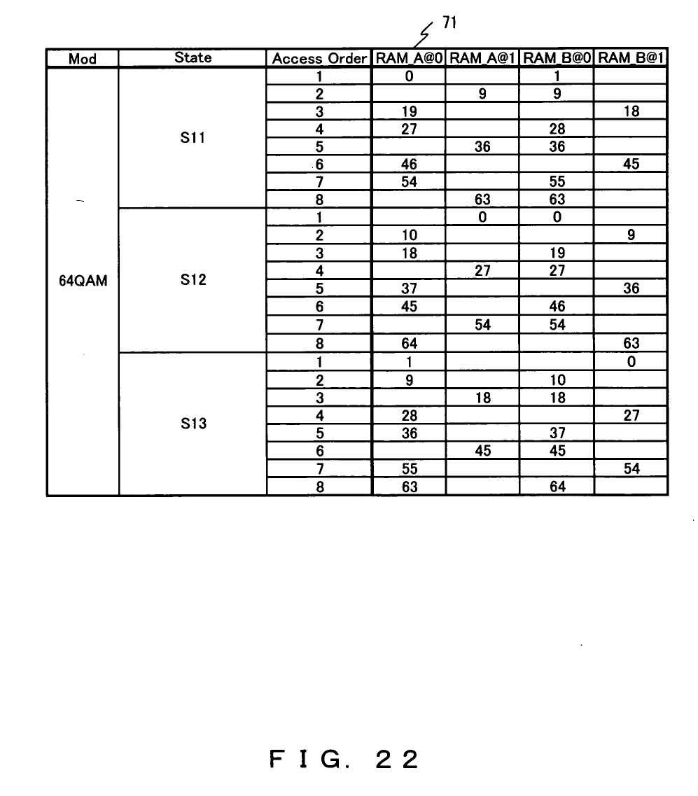

The next description is of a readout operation in the case of de-interleaving input data which has been interleaved by the 64 QAM modulation, in reference to FIGS. 21 and 22.

FIG. 21 shows a state of data, which has been interleaved by the 64 QAM modulation, and is stored by the RAM A@0, RAM_A@1, RAM_B@0 and RAM_B@1.

It is assumed that the RAM_A@0, RAM_A@1, RAM_B@0 and RAM_B@1 shown by FIG. 21 store data as shown by the output of FIG. 20.

The alphabet characters A, B, C, D, E and F in the rectangular frames of the respective RAM_A@0, RAM_A@1, RAM_B@0 and RAM_B@1 shown by FIG. 21 indicate data stored by the respective memory areas. And the numbers such as 0, 8, 9, 17, 18, 26, et cetera, written above the upper left and upper right ends (viewed from the front of FIG. 21) of the respective RAM indicate addresses, with the [1], [2], [3], and so on, corresponding to the data [1], [2], [3], and so on, of the RAM 17 shown by FIG. 7. And the alphabetic characters A, B, C, D, E and F in the rectangular frames of the respective RAM_A@0, RAM_A@1, RAM_B@0 and RAM_B@1 corresponding to the columns A0 through F2 which correspond to the columns <0> through <17> of the structure of the RAM 17 shown by FIG. 7A. That is, the alphabetic character A shown by FIG. 21 corresponds to the data in the columns A0, A1 and A2 shown by FIG. 7A, and likewise for the alphabet characters B through F.

FIG. 22 shows an address table 71 for correlating the states S11 through S13 with the addresses of RAM which are then selected.

Let a data reading operation of a de-interleaving be described specifically, by using FIG. 21 while referring to the address table 71.

In the access order 1 of the state S11, the RAM_A@0 and RAM_B@0 are selected, and the addresses “0” and “1” are specified, as indicated by the access order 1 of the address table 71 shown by FIG. 22.

As a result of the above, the data A of the address “0” of the RAM_A@0 and the data A of the address “1” of the RAM_B@0 are read out as shown by FIG. 21 (1).

In the access order 2 of the state S11, the RAM_A@1 and RAM_B@0 are selected, and the respective addresses “9” and “9” are specified, as indicated by the address table 71 shown by FIG. 22.

As a result, the data A of the address “9” of the RAM_A@1 and the data A of the address “9” of the RAM_B@0 are read out at the same time as shown by FIG. 21 (2).

In the access order 3 of the state S11, the RAM_A@0 and RAM_B@1 are selected, and the respective addresses “19” and “18” are specified, as indicated by the address table 71 shown by FIG. 22.

As a result, the data A of the address “19” of the RAM_A@0 and the data A of the address “18” of the RAM B@0 are read out at the same time as shown by FIG. 21 (3).

Likewise as described above, in the following data are sequentially read out of addresses of the RAM_A and RAM_B, which are specified by the access orders 4 through 8 of the address table 71 shown by FIG. 22.

In the access order 1 of the state S12, the RAM_A@1 and RAM_B@0 are selected, and the respective addresses “0” and “0” are specified, as indicated by the state S12 of the address table 71 shown by FIG. 22.

As a result, the data B of the address “0” of the RAM_A@1 and the data B of the address “0” of the RAM_B@0 are read out at the same time as shown by FIG. 21 (1).

In the access order 2 of the state S12, the RAM_A@0 and RAM_B@1 are selected, and the respective addresses “10” and “9” are specified, as indicated by the state S12 of the address table 71 shown by FIG. 22.

As a result, the data B of the address “10” of the RAM_A@0 and the data B of the address “9” of the RAM_B@1 are read out at the same time as shown by FIG. 21 (2).

Likewise as above described in the following, data are sequentially read out of addresses which are specified by the access orders 3 through 8 of the state S12.

Furthermore, in the access order 1 of the state S13, the RAM_A@0 and RAM_B@1 are selected, and the respective addresses “1” and “0” are specified, as indicated by the state S13 of the address table 71 shown by FIG. 22.

As a result, the data C of the address “1” of the RAM_A@0 and the data C of the address “0” of the RAM_B@1 are read out at the same time as shown by FIG. 21 (1).

Likewise as above described in the following, data are read out of the addresses which are specified by the access orders 2 through 8 of the state S13.

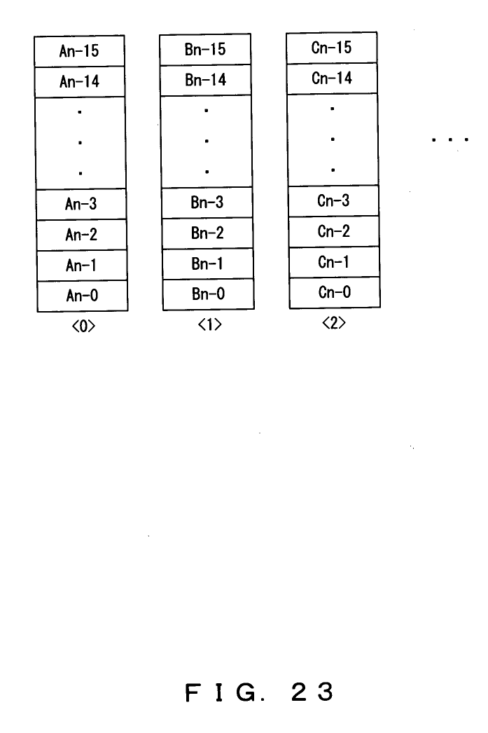

The above described readout operations read out the data An-0 through An-15 (where n=0, 1, 2) of the input data string which have been rearranged by an interleaving processing at the time of a transmission as shown by FIG. 23, followed by reading out the respective data of the data strings Bn, Cn, and so on, and rearranging them to the original sequences.

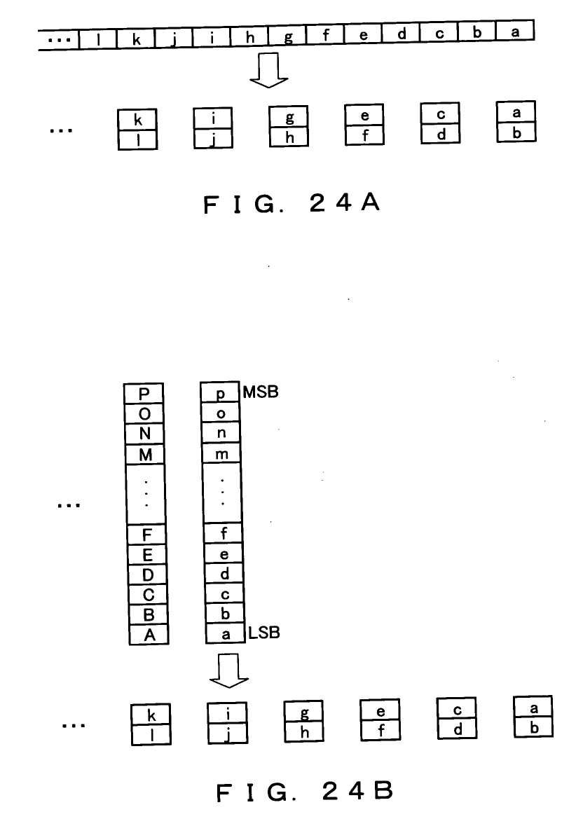

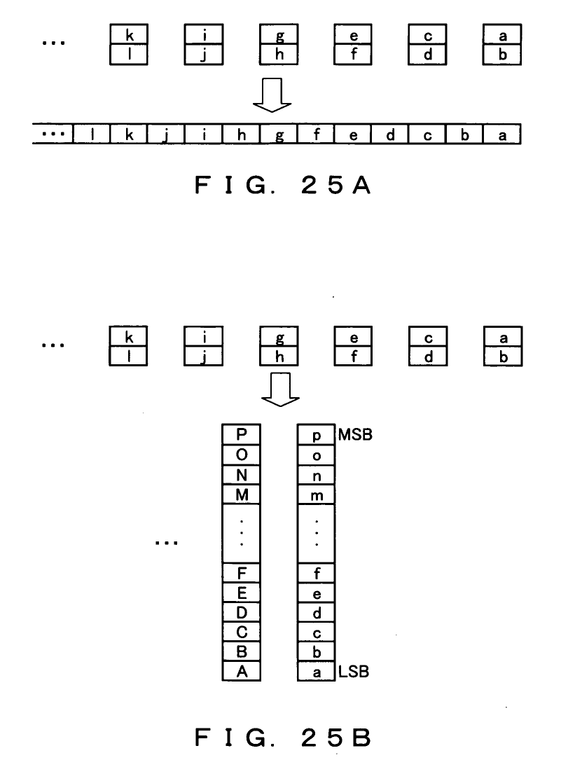

FIGS. 24 and 25 describe a data rearrangement by the data rearrangement unit 19.

In the case of a circuit on the output side, by receiving a serial input, requiring 2-bit parallel data, the data rearrangement unit 19 converts the serial data to 2-bit parallel data and outputs as shown by FIG. 24A, while, in the case of a parallel input, converting the parallel data to 2-bit parallel data sequentially beginning from the lower bit, and outputs it, as shown by FIG. 24B.

Meanwhile, in the case of input data being 2-bit parallel data and a circuit on the output side requiring serial data, the 2-bit parallel data is converted to serial data for outputting as shown by FIG. 25A, while in the case of a circuit on the output side requiring parallel data, the 2-bit parallel data is converted to a prescribed bit-number parallel data for outputting as shown by FIG. 25B.

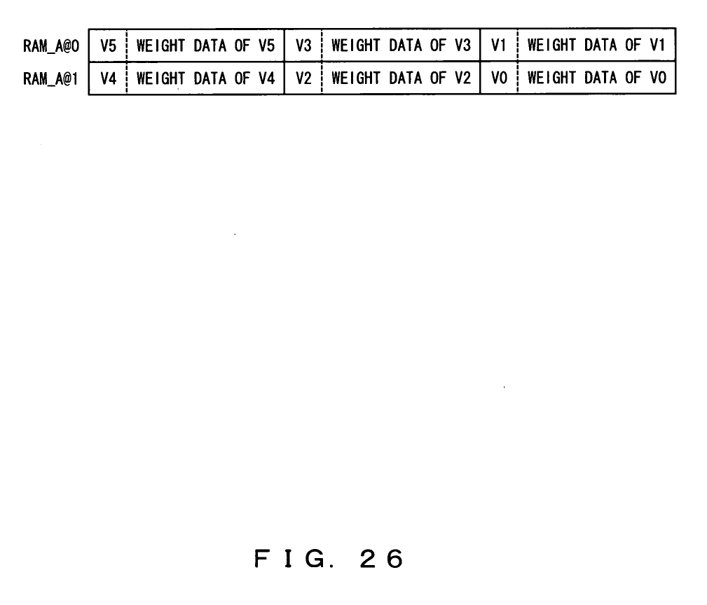

As another embodiment, FIG. 26 shows data stored by the RAM_A@0 and RAM_A@1 in the case of adding weight data that indicates a weighting of data to restore the data.

The weight data indicates that each bit value is close to either zero (0) or one (1), and is added in the unit of one bit. The addition of the weight data makes it possible to reduce a demodulation error in the respective bit data V5, V3, V1, et cetera. A valid weight data is not added at the time of modulation, that is, of a transmission.

In the case of adding weight data, a rearrangement processing is carried out by handling a single data including the weight data. At the time of an interleaving, only the respective bit data V5, V4, V3, et cetera, are extracted for outputting. Since the weight data is invalid, its value is not important. Weight information is included in an output at the time of a de-interleaving.

The above described embodiment is configured such that the state control 12 outputs mode-1 state information and mode-2 state information; the ROM address control 13 specifies a readout address of the address ROM 16 based on the aforementioned pieces of state information; and the RAM address control 14 and the RAM access control 15 write data to the RAM 17 by selecting it and specifying the addresses thereof, thereby enabling a rearrangement of the input data according to a prescribed rearrangement rule. And the configuration is so as to read out data by specifying addresses of the RAM 17, thereby making it possible to restore the interleaved data to the original sequence by rearranging it.

The present embodiment is configured to carry out an interleaving and de-interleaving processing by a common circuit, thereby reducing a size of a circuit for carrying out the interleaving and de-interleaving processing and accordingly reducing the power consumption. Reduction of a circuit size can make a chip size compact when configuring a semiconductor apparatus by forming a wireless telecommunication circuit including the interleaving and de-interleaving processing unit 11 on a semiconductor circuit board.

Note that the above described embodiment is configured to rearrange data at the time of writing the data to the RAM 17 in ,the case of carrying out an interleaving processing, the rearrangement of data may be carried out when reading the data out of the RAM 17, however. Conversely, rearrangement of data may be carried out when writing the data to the RAM 17 in the case of a de-interleaving processing.

The present invention enables a common circuit for an interleaving processing and a de-interleaving processing, thereby making the circuit small and accordingly reducing the power consumption.

The present invention may be configured as follows, in lieu of being limited by the above described embodiment:

(1) A configuration of the interleaving and de-interleaving processing unit 11 may be any known circuit provided that the same function is accomplished, in lieu of being limited by FIGS. 3 and 4.

(2) Although the embodiment is configured to add address data, which is read out of the address ROM 16, to a unit offset, it may be configured to let the address ROM 16 store all data so as to eliminate an addition of a unit offset. Alternatively, an integrated form is possible by letting the RAM address control 14 include the address ROM 16. Alternatively, another integrated form is possible by letting the RAM address control 14 include the ROM address control 13 and the address ROM 16.

(3) The present invention is applicable to a wireless apparatus and other apparatuses, in lieu of being limited to a wireless LAN.

(4) Although the embodiment is configured such that the RAM 17 comprises eight pieces of RAM, two pieces, i.e., a set #0 and a set #1, are possible in lieu of being limited to the eight, or a plurality thereof may not be necessary if there is no requirement for simultaneous processing of the mode-1 and mode-2. Alternatively, one piece of RAM may be operated by dividing the one into eight pieces in a virtual space.

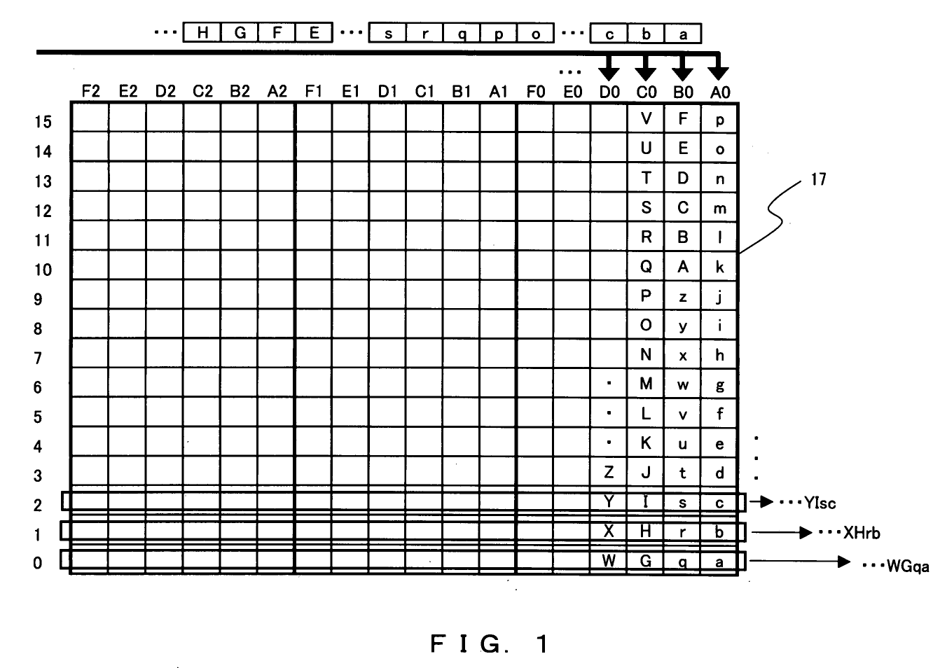

(5) The “rearrangement” defined in the embodiment indicates an operation including the rearrangement shown by FIG. 2, it may an operation including both of the rearrangement shown by FIG. 1 and the one shown by FIG. 2.

What is claimed is:

1. An interleaving and de-interleaving method for rearranging data,
for making a state control unit output state information for the purpose of selecting a RAM (random access memory) as the access target from among a plurality of RAM and specifying an address, wherein
the state control unit outputs state information of a first mode for rearranging data and that of a second mode for not rearranging data.

2. The interleaving and de-interleaving method for rearranging data according to claim 1, for making:
a state control unit output state information for the purpose of selecting a RAM as the access target from among a plurality of RAM and specifying an address,
address data for specifying addresses, which are stored by a ROM (read only memory), of the plurality of RAM outputted by specifying readout addresses of the ROM based on the state information, and
a selection signal for selecting a RAM as the access target outputted based on the state information, wherein
the state control unit outputs state information of a first mode for rearranging data and that of a second mode for not rearranging data.

3. The interleaving and de-interleaving method according to claim 2,
for making an address, which is an addition of a unit offset determined by said state information and address data outputted from said ROM, outputted to said RAM as the access target.

4. The interleaving and de-interleaving method according to claim 2,
for rearranging data by specifying an address of a RAM as the access target among said plurality of RAM based on said state information of said first mode and reading out, or writing data, and at the same time carrying out either writing or reading data without rearranging the data by specifying an address of a RAM as the access target among the plurality of RAM based on said state information of said second mode.

5. The interleaving and de-interleaving method according to claim 2, for
outputting a selection signal for selecting said RAM as the access target based on said state information of said first mode and, at the same time,
outputting a signal for specifying whether to make the RAM as the access target assume a writing state or a readout state based on said state information of said second mode.

6. The interleaving and de-interleaving method according to claim 2, for
outputting an address to said ROM, as a readout address, which is obtained by an addition of an address determined corresponding to each state information of each modulation method and a base address changed by a first timing signal which is synchronized with data.

7. The interleaving and de-interleaving method according to claim 2, for
outputting an address, which is obtained by an addition of an address output from said ROM and a predetermined unit offset determined by said state information of said first mode, to said RAM.

8. A wireless apparatus having an interleaving and de-interleaving function for rearranging data in a prescribed sequence, comprising
a state control unit for outputting state information for the purpose of selecting a RAM as the access target from among a plurality of RAM and specifying an address, with the state information including the one of a first mode for rearranging data and that of a second mode for not rearranging data.

9. A wireless apparatus having an interleaving and de-interleaving function for rearranging data in a prescribed sequence, comprising:
a state control unit for outputting state information for the purpose of selecting a RAM as the access target from among a plurality of RAM and specifying an address;
a ROM for memorizing address data for specifying addresses of the plurality of RAM;
a ROM address control unit for specifying a readout address of the ROM based on the state information; and
a RAM access control unit for outputting a selection signal for selecting a RAM as the access target among the plurality of RAM based on the state information, wherein
the state control unit outputs state information of a first mode for rearranging data and that of a second mode for not rearranging data.

10. The wireless apparatus according to claim 9, wherein
said state control unit comprises
a first mode state control unit for outputting state information of a first mode for rearranging data based on a first timing signal synchronized with information indicating a modulation system and data, and
a second mode state control unit for outputting state information of a second mode for not rearranging data based on a second timing signal synchronized with the data.

11. The wireless apparatus according to claim 9, comprising
a RAM address control unit which outputs
an address, which is obtained by an addition of address data output from said ROM and a unit offset determined by said state information, to said RAM as the access target.

12. The wireless apparatus according to claim 11, wherein
said RAM address control unit
rearranges data by specifying an address of a RAM as the access target among said plurality of RAM based on said state information of said first mode and reading out, or writing data and, at the same time,
carries out either writing or reading data without rearranging the data by specifying an address of a RAM as the access target among the plurality of RAM based on said state information of said second mode.

13. The wireless apparatus according to claim 11, wherein
said RAM access control unit
outputs a selection signal for selecting a RAM as said access target based on said state information of said first mode, and, at the same time,
outputs a signal for specifying whether the RAM as the access target assumes a writing state or a readout state based on said state information of said second mode.

14. The wireless apparatus according to claim 11, wherein
said ROM address control unit
outputs an address to said ROM, which is obtained by an addition of an address determined corresponding to each state information of each modulation method and a base address that changes synchronously with a first timing signal which is synchronized with data.

15. A semiconductor apparatus comprising an interleaving and de-interleaving process unit for rearranging data in a prescribed sequence, comprising on a semiconductor integrated circuit board:
a state control circuit for outputting state information for the purpose of selecting a RAM as the access target from among a plurality of RAM and specifying an address;
a ROM for memorizing address data for specifying addresses of the plurality of RAM;
a ROM address control circuit for specifying a readout address of the ROM based on the state information;
a RAM address control circuit for specifying an address of a RAM as the access target among the plurality of RAM based on address data output from the ROM; and
a RAM access control circuit for outputting a selection signal for selecting a RAM as the access target among the plurality of RAM based on the state information.

16. The semiconductor apparatus according to claim 15, wherein
said ROM address control circuit outputs an address to said ROM, which is obtained by an addition of an address determined corresponding to each state information of each modulation method and a base address that changes synchronously with a first timing signal which is synchronized with data.

17. The semiconductor apparatus according to claim 15, wherein
said state control circuit outputs state information of a first mode for rearranging data and that of a second mode for not rearranging data.

18. The semiconductor apparatus according to claim 17, wherein
said RAM address control unit
rearranges data by specifying an address of a RAM as the access target among said plurality of RAM based on said state information of said first mode and reading out, or writing, data, and, at the same time,
outputs an address of another RAM as the access target among the plurality of RAM based on said state information of said second mode.

19. The semiconductor apparatus according to claim 17, wherein
said RAM access control circuit
outputs a selection signal for selecting a RAM as said access target based on said state information of said first mode, and, at the same time,
outputs a signal for specifying whether the RAM as the access target assumes a writing state or a readout state based on said state information of said second mode.

20. A wireless apparatus comprising an interleaving and de-interleaving function for rearranging data in a prescribed sequence, comprising:
a RAM for writing, and reading out, data; and
a state control unit, wherein
the state control unit specifies an address of the RAM and carries out an interleaving and an de-interleaving processings.

21. A semiconductor apparatus comprising an interleaving and de-interleaving process unit for rearranging data in a prescribed sequence, comprising:
a RAM for writing, and reading out, data; and
a state control unit, wherein
the state control unit outputs a first mode state information and a second mode state information for carrying out an interleaving processing and a de-interleaving processing.
